(19) United States
(12) Patent Application Publication
(10) Pub. No.: US 2023/0137108 A1
(43) Pub. Date: May 4, 2023

(54) SEMICONDUCTOR INTERCONNECT STRUCTURES AND METHODS OF FORMATION

(71) Applicant: Taiwan Semiconductor Manufacturing Company Limited, Hsinchu (TW)

(72) Inventors: Kan-Ju LIN, Kaohsiung City (TW); Chien CHANG, Hsinchu (TW); Chih-Shiun CHOU, Hsinchu City (TW); Tai Min CHANG, Taipei City (TW); Hung-Yi HUANG, Hsin-chu City (TW); Chih-Wei CHANG, Hsin-Chu (TW); Ming-Hsing TSAI, Chu-Pei City (TW); Lin-Yu HUANG, Hsinchu (TW)

(21) Appl. No.: 17/647,263

(22) Filed: Jan. 6, 2022

Related U.S. Application Data
(60) Provisional application No. 63/263,411, filed on Nov. 2, 2021.

(51) Int. Cl. H01L 21/768; H01L 23/522

(52) U.S. Cl. CPC H01L 21/76883; H01L 21/76816; H01L 23/5226; H01L 21/7684; H01L 23/53209

(57) ABSTRACT

Techniques described herein include performing a first anneal operation on a first portion of the interconnect, filling the remaining portion of the interconnect, and then performing a second anneal operation on the interconnect. The two-step anneal techniques described herein enable the removal of defects in an interconnect structure, particularly for high aspect ratio interconnect structures. Accordingly, the two-step anneal techniques described herein may be used to fabricate defect free or near defect free interconnect structures in a semiconductor device. This reduces contact resistance for the interconnect structures, reduces premature device failure for the semiconductor device, increases manufacturing yield, and increases tolerance of the interconnect structures to subsequent processing operations, among other examples.

### CROSS-REFERENCE TO RELATED APPLICATION

This Patent Application claims priority to U.S. Provisional Patent Application No. 63/263,411, filed on Nov. 2, 2021, and entitled “SEMICONDUCTOR INTERCONNECT STRUCTURES AND METHODS OF FORMATION.” The disclosure of the prior Application is considered part of and is incorporated by reference into this Patent Application.

### BACKGROUND

An electronic device (e.g., a processor, a memory) may include various intermediate and backend layers or regions in which individual semiconductor devices (e.g., transistors, capacitors, resistors) are interconnected by interconnect structures. The interconnect structures may include metallization layers (also referred to as wires), vias that connect the metallization layers, contact plugs, and/or trenches, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example of a portion of a semiconductor device described herein.

FIGS. 3-6 are diagrams of example implementations of semiconductor structures described herein.

FIGS. 7A-7G, 8A-7F, 9A-9F, and 10A-10F are diagrams of example implementations described herein.

FIGS. 11 and 12A-12D are diagrams of other example implementations of a portion of the semiconductor device of FIG. 2 described herein.

FIG. 13 is a diagram of example components of one or more devices of FIG. 1 described herein.

FIGS. 14 and 15 are flowcharts of example processes relating to forming a semiconductor interconnect structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the semiconductor industry, there are continued efforts to reduce the size of integrated circuits (ICs) and structures included therein (e.g., transistors, contacts, interconnects). The reduction in IC can be facilitated through the reduction in horizontal width of the structures included therein, which leads to an increase in aspect ratio (e.g., between height/depth and width) of the structures. This enables greater device density, reduced power, and greater IC performance. However, shrinking structure sizes and increased aspect ratios magnify the effects of semiconductor manufacturing defects, such as voids, cracks, discontinuities, and/or impurities. These defects can increase contact resistance, can lead to premature device failure, and can lead to reduced manufacturing yield, among other examples. Moreover, these defects can be worsened by subsequent processes such as CMP and plasma-based etching.

Some implementations described herein provide two-step anneal techniques in which an interconnect structure (e.g., a gate interconnect (via-to-gate, VG) or a source/drain interconnect (via-to-source/drain, VD)) is formed by performing a first anneal operation on a first portion of the interconnect, filling the remaining portion of the interconnect, and then performing a second anneal operation on the interconnect. The first portion of the interconnect is annealed in the first anneal operation to remove defects (such as voids) that might otherwise be unreachable from the top of the interconnect due to the high aspect ratio of the interconnect. The two-step anneal techniques described herein enable the removal of defects (e.g., voids) in an interconnect structure, particularly for high aspect ratio interconnect structures. Accordingly, the two-step anneal techniques described herein may be used to fabricate defect free or near defect free interconnect structures in a semiconductor device. This reduces contact resistance for the interconnect structures, reduces premature device failure for the semiconductor device, increases manufacturing yield, and increases tolerance of the interconnect structures to subsequent processing operations, among other examples.

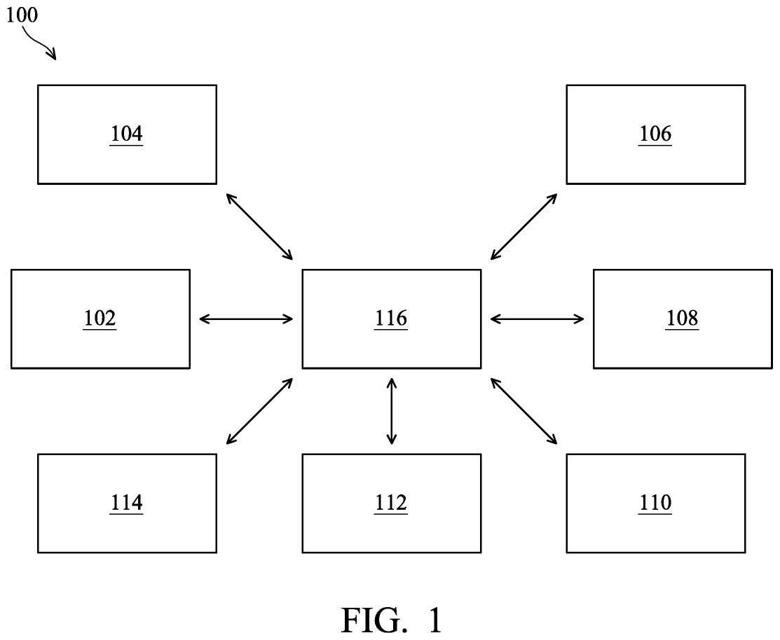

FIG. 1 is a diagram of an example environment 100 in which systems and/or methods described herein may be implemented. As shown in FIG. 1, environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, an annealing tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The annealing tool 114 is a semiconductor processing tool that includes a semiconductor processing chamber and one or more devices capable of heating a semiconductor substrate or semiconductor device. For example, the annealing tool 114 may include a rapid thermal annealing (RTA) tool or another type of annealing tool that is capable of heating a semiconductor substrate to cause a reaction between two or more materials or gasses, to cause a material to decompose. As another example, the annealing tool 114 is configured to heat (e.g., raise or elevate the temperature of) metal structures (or portions thereof) to re-flow the metal structures (e.g., to cause the metal structures to transition from solid form to liquid form, or a form in which the material of the metal structures is enabled to flow) to remove defects from the metal structures, as described herein.

The wafer/die transport tool 116 includes a mobile robot, a robot arm, a tram or rail car, an overhead hoist transport (OHT) system, an automated materially handling system (AMHS), and/or another type of device that is used to transport wafers and/or dies between semiconductor processing tools 102-114 and/or to and from other locations such as a wafer rack, a storage room, and/or the like. In some implementations, the wafer/die transport tool 116 may be a programmed device that is configured to travel a particular path and/or may operate semi-autonomously or autonomously.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of environment 100 may perform one or more functions described as being performed by another set of devices of environment 100.

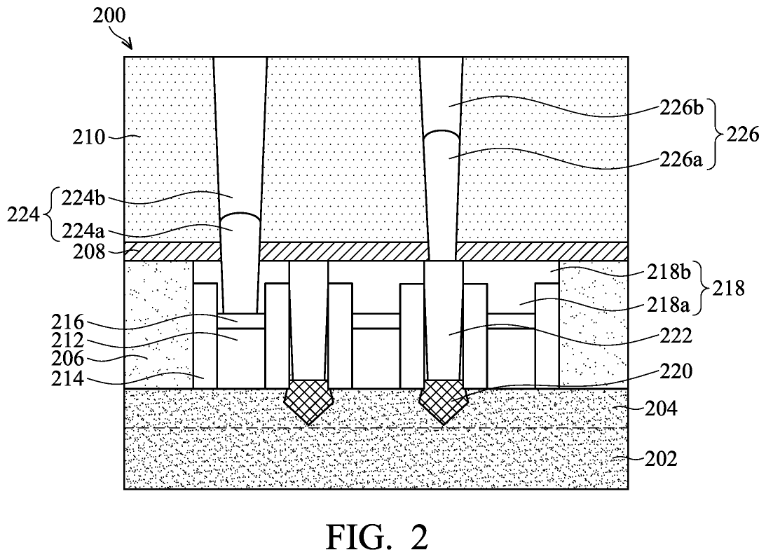

FIG. 2 is a diagram of a portion of a semiconductor device 200 described herein. The portion of the semiconductor device 200 includes an example of a memory device (e.g., a static random access memory (SRAM), a dynamic random access memory (DRAM)), a logic device, a processor, an input/output device, or another type of semiconductor device that includes one or more transistors.

As shown in FIG. 2, the semiconductor device 200 includes a device substrate 202, which includes a silicon (Si) substrate, a substrate formed of a material including silicon, a III-V compound semiconductor material substrate such as gallium arsenide (GaAs), a silicon on insulator (SOI) substrate, a silicon germanium (SiGe) substrate, or another type of semiconductor substrate. In some implementations, a fin structure 204 is formed in the device substrate 202. In some implementations, a plurality of fin structures 204 are included in the device substrate 202. In this way, the transistors included on the semiconductor device 200 include fin field-effect transistors (finFETs). In some implementations, the semiconductor device 200 includes other types of transistors, such as gate all around (GAA) transistors (e.g., nanosheet transistors, nanowire transistors, nanostructure transistors), planar transistors, and/or other types of transistors. The fin structures 204 are electrically isolated by intervening shallow trench isolation (STI) structures or regions (not shown). The STI structures may be etched back such that the height of the STI structures is less than the height of the fin structures 204. In this way, the gate structures of the transistors may be formed around at least three sides of the fin structures 204.

As shown in FIG. 2, a plurality of layers are included on the device substrate 202 and/or on the fin structures 204, including a dielectric layer 206, an etch stop layer (ESL) 208, and a dielectric layer 210, among other examples. The dielectric layers 206 and 210 are included to electrically isolate various structures of the semiconductor device 200. The dielectric layers 206 and 210 include interlayer dielectric layers (ILDs). For example, the dielectric layer 206 may include an ILDO layer, and the dielectric layer 210 may include an ILD1 layer or an ILD2 layer (in some cases, the ILD1 layer is skipped).

The thickness of the dielectric layer 210 may be included in a range of approximately 3 nanometers to approximately 40 nanometers to provide sufficient height or depth for forming the interconnect structures of the semiconductor device 200 without unduly increasing the height of the semiconductor device 200. However, other values for the thickness of the ESL 208 are within the scope of the present disclosure. The dielectric layers 206 and 210 each include (e.g., either the same material or different materials) a lanthanum oxide (LaₓO_{y}), an aluminum oxide (AlₓO_{y}), a yttrium oxide (YₓO_{y}), a tantalum carbon nitride (TaCN), a zirconium silicide (ZrSix), a silicon oxycarbonitride (SiOCN), a silicon oxycarbide (SiOC), a silicon carbon nitride (SiCN), a zirconium nitride (ZrN), a zirconium aluminum oxide (ZrAlO), a titanium oxide (TiₓO_{y}), a tantalum oxide (TaₓO_{y}), a zirconium oxide (ZrxO_{y}), a hafnium oxide (HfxO_{y}), a silicon nitride (SiₓN_{y}), a hafnium silicide (HfSiₓ), an aluminum oxynitride (AlON), a silicon oxide (SiₓO_{y}), a silicon carbide (SiC), a zinc oxide (ZnₓO_{y}), and/or another dielectric material.

The thickness of the ESL 208 may be included in a range of approximately 3 nanometers to approximately 20 nanometers to provide sufficient etch selectivity without unduly increasing the height of the semiconductor device 200. However, other values for the thickness of the ESL 208 are within the scope of the present disclosure. The ESL 208 includes a layer of material that is configured to permit various portions of the semiconductor device 200 (or the layers included therein) to be selectively etched or protected from etching to form one or more of the structures included on the device substrate 202. The ESL 208 may include a lanthanum oxide (LaₓO_{y}), an aluminum oxide (AlₓO_{y}), a yttrium oxide (YₓO_{y}), a tantalum carbon nitride (TaCN), a zirconium silicide (ZrSix), a silicon oxycarbonitride (SiOCN), a silicon oxycarbide (SiOC), a silicon carbon nitride (SiCN), a zirconium nitride (ZrN), a zirconium aluminum oxide (ZrAlO), a titanium oxide (TiₓO_{y}), a tantalum oxide (TaₓO_{y}), a zirconium oxide (ZrₓO_{y}), a hafnium oxide (HfₓO_{y}), a silicon nitride (SiₓN_{y}), a hafnium silicide (HfSiₓ), an aluminum oxynitride (AlON), a silicon oxide (SiₓO_{y}), a silicon carbide (SiC), and/or a zinc oxide (ZnₓO_{y}), among other examples.

As further shown in FIG. 2, a plurality of gate stacks may be included over, on, and/or around a portion of the fin structure 204. The gate stacks include a metal gate (MG) structure 212 between sidewall spacers 214, a metal capping layer 216 over and/or on the metal gate structure 212, and a dielectric capping layer 218 over and/or on the metal capping layer 216. The metal gate structures 212 include a conductive metallic material (or metal alloy) such as cobalt (Co), tungsten (W), ruthenium (Ru), molybdenum (Mo), titanium (Ti), titanium nitride (TiN), another metallic material, and/or a combination thereof. The sidewall spacers 214 are included to electrically isolate the gate stacks from adjacent conductive structures included on the semiconductor device 200, and thus may be referred to as gate spacers. The sidewall spacers 214 include a silicon oxide (SiOₓ), a silicon nitride (SiₓN_{y}), a silicon oxy carbide (SiOC), a silicon oxycarbonitride (SiOCN), and/or another suitable material.

The metal capping layer 216 is included to protect the metal gate structure 212 from oxidization and/or etch damage during processing of the semiconductor device 200, which preserves the low contact resistance of the metal gate structure 212. The metal capping layer 216 include a conductive metallic material (or metal alloy) such as cobalt (Co), tungsten (W), ruthenium (Ru), molybdenum (Mo), titanium (Ti), titanium nitride (TiN), another metallic material, and/or a combination thereof. The dielectric capping layer 218 includes a dielectric material such as a lanthanum oxide (LaₓO_{y}), an aluminum oxide (AlₓO_{y}), a yttrium oxide (YₓO_{y}), a tantalum carbon nitride (TaCN), a zirconium silicide (ZrSiₓ), a silicon oxycarbonitride (SiOCN), a silicon oxycarbide (SiOC), a silicon carbon nitride (SiCN), a zirconium nitride (ZrN), a zirconium aluminum oxide (ZrAlO), a titanium oxide (TiₓO_{y}), a tantalum oxide (TaₓO_{y}), a zirconium oxide (ZrₓO_{y}), a hafnium oxide (HfₓO_{y}), a silicon nitride (SiₓN_{y}), a hafnium silicide (HfSiₓ), an aluminum oxynitride (AlON), a silicon oxide (SiₓO_{y}), a silicon carbide (SiC), and/or a zinc oxide (ZnₓO_{y}), among other examples.

The dielectric capping layer 218 may be referred to as a sacrificial (SAC) layer that protects the gate stacks from processing damage during processing of the semiconductor device 200. In some implementations, the dielectric capping layer 218 includes a first portion 218a (e.g., a lower portion) between a pair of sidewall spacers 214, where the first portion 218a extends from a top surface of an associated metal capping layer 216 to the same approximately height or top surface level of the sidewall spacers 214. In these implementations, the dielectric capping layer 218 further includes a second portion 218b (e.g., an upper portion) that extends above the first portion 218a and over the top surfaces of the sidewall spacers 214, as shown in FIG. 2. In some other implementations, the sidewall spacers 214 fully extend between the fin structure 204 (or the device substrate 202) and the ESL 208, and the dielectric capping layer 218 is fully contained between the sidewall spacers 214 between the top surface of the associated metal capping layer 216 and the bottom surface of the ESL 208.

As further shown in FIG. 2, a plurality of source/drain regions 220 are included on and/or around portions of the fin structure 204. The source/drain regions 220 include p-doped and/or n-doped epitaxial (epi) regions that are grown and/or otherwise formed by epitaxial growth. In some implementations, the source/drain regions 220 are formed over etched portions of the fin structure 204. The etched portions may be formed by strained source drain (SSD) etching of the fin structure 204 and/or another type etching operation.

Metal source/drain contacts (MDs) 222 are included over and/or on the source/drain regions 220. In some implementations, a metal silicide layer (not shown) is included between the source/drain regions 220 and the metal source/drain contacts 222 due to a reaction between the source/drain regions 220 and the metal source/drain contacts 222. The metal silicide layer may be included to decrease contact resistance between the source/drain regions 220 and the metal source/drain contacts 222 and/or to decrease the Schottky barrier height (SBH) between the source/drain regions 220 and the metal source/drain contacts 222. The metal source/drain contacts 222 include conductive metallic material (or metal alloy) such as cobalt (Co), tungsten (W), ruthenium (Ru), copper (Cu), another metallic material, and/or a combination thereof.

In some implementations, a contact etch stop layer (CESL) is included between the sidewall spacers of the gate stacks and the metal source/drain contacts 222. The CESL may be included to provide etch selectivity or etch stop point for the sidewall spacers 214 during an etch operation to form openings in which the metal source/drain contacts 222 are formed.

As further shown in FIG. 2, the metal gate structures 212 (e.g., either directly or via the metal capping layer 216) and the metal source/drain contacts 222 are electrically and/or physically connected to interconnect structures. For example, a metal gate structure 212 may be electrically connected to a gate interconnect structure 224 (e.g., a gate via or VG). The metal gate structure 212 is electrically and/or physically connected to the gate interconnect structure 224 directly, via the intervening metal capping layer 216, and/or by a metal gate contact (MP). As another example, a metal source/drain contact 222 are electrically and/or physically connected to a source/drain interconnect structure 226 (e.g., a source/drain via or VD). The interconnect structures (e.g., the gate interconnect structure 224, the source/drain interconnect structure 226, among other examples) electrically connect the transistors on the semiconductor device 200 and/or electrically connect the transistors to other areas and/or components of the semiconductor device 200. In some implementations, the interconnect structures electrically connect the transistors to a back end of line (BEOL) region of the semiconductor device 200. The gate interconnect structure 224 and the source/drain interconnect structure 226 include a conductive material such as tungsten, cobalt, ruthenium, copper, and/or another type of conductive material.

As further shown in FIG. 2, the gate interconnect structure 224 includes a two-part structure including a first part 224a and a second part 224b. The first part 224a is orientated toward the metal gate structure 212 and is electrically (and/or physically) connected with the metal gate structure 212 either directly or by the metal capping layer 216 (e.g., where metal capping layer 216 functions as an intervening conductive layer, and the top surface of the metal capping layer 216 is lower than the top surfaces of the associated sidewall spacers 214). The second part 224b is included over and/or on the first part 224a. In some implementations, the height or thickness of the first part 224a and/or the height or thickness of the second part 224b is greater relative to a height or thickness of the metal capping layer 216. In some implementations, the height or vertical position of a top surface of the first part 224a and/or the height or vertical position of a top surface of the second part 224b is greater relative to a height or vertical position of a top surface of the metal source/drain contact 222.

As described herein, the first part 224a and the second part 224b are formed by respective and separate deposition operations, which result in the two-part structure of the gate interconnect structure 224. As a result, an interface between the first part 224a and the second part 224b is located at a location along the depth (or height) of the gate interconnect structure 224. The interface may be visible in the electron microscope imaging of the gate interconnect structure 224 (e.g., in a transmission electron microscopy (TEM) image of the gate interconnect structure 224) as a result of, for example, slight oxidation or nitridation at the top surface of the first part 224a prior to deposition of the second part 224b. While the interface is shown as being located at the same level as the dielectric layer 210 (e.g., at a height or depth that is between the bottom surface and the top surface of the dielectric layer 210), the first part 224a and the second part 224b may be formed such that the interface is located at another level in the semiconductor device 200 such as at the same level as the ESL 208 or the same level as the dielectric capping layer 218 (e.g., the first portion 218a or the second portion 218b), among other examples. The location of the interface between the first part 224a and the second part 224b may be based on a height of the gate interconnect structure 224, a width of the gate interconnect structure 224, an aspect ratio of the gate interconnect structure 224, a type of material that is used to form the first part 224a, a type of material that is used to form the second part 224b, and/or another factor.

The formation of the first part 224a and the second part 224b by respective and separate deposition operations further enables the first part 224a and the second part 224b to be formed of different conductive materials or different conductive material compositions including one or more conductive materials. For example, the first part 224a may include a first conductive material composition including one or more first conductive materials, the second part 224b may include a second conductive material composition including one or more second conductive materials, where the first conductive material composition and the second conductive material composition are different material compositions. This enables further flexibility in the semiconductor processes of forming the gate interconnect structure 224 and enables the formation of more complex and higher performance gate interconnect structures 224. Although, the first part 224a and the second part 224b being formed of the same material or same material composition is within the scope of the present disclosure. In some implementations, the first part 224a includes a conductive material such as tungsten (W), ruthenium (Ru), molybdenum (Mo), cobalt (Co), copper (Cu), another conductive material, a conductive material composition of one or more of the preceding conductive materials, or a combination thereof. In some implementations, the second part 224b includes a conductive material such as tungsten (W), ruthenium (Ru), molybdenum (Mo), cobalt (Co), copper (Cu), aluminum (Al), titanium (Ti), titanium nitride (TiN), another conductive material, a conductive material composition of one or more of the preceding conductive materials, or a combination thereof.

In some implementations, the grain size of the material of the first part 224a and the grain size of the material of the second part 224b are approximately the same grain size. In some implementations, the grain size of the material of the first part 224a and the grain size of the material of the second part 224b are different grain sizes. For example, the grain size of the material of the first part 224a may be greater than the grain size of the material of the second part 224b. As another example, the grain size of the material of the second part 224b may be greater than the grain size of the material of the first part 224a.

As further shown in FIG. 2, the source/drain interconnect structure 226 includes a two-part structure including a first part 226a and a second part 226b.The first part 226a is orientated toward an associated metal source/drain contact 222 and is electrically (and/or physically) connected with the metal source/drain contact 222 either directly or by one or more liners and/or barrier layers. The second part 226b is included over and/or on the first part 226a. In some implementations, the height or vertical position of a top surface of the first part 226a and/or the height or vertical position of a top surface of the second part 226b is greater relative to a height or vertical position of a top surface the metal capping layer 216. In some implementations, the height or thickness of the first part 226a and/or the height or thickness of the second part 226b is greater relative to a height or thickness of the metal source/drain contact 222.

As described herein, the first part 226a and the second part 226b are formed by respective and separate deposition operations, which results in the two-part structure of the source/drain interconnect structure 226. As a result, an interface between the first part 226a and the second part 226b is located at a location along the depth (or height) of the source/drain interconnect structure 226. The interface may be visible in the electron microscope imaging of the gate interconnect structure 224 (e.g., in a TEM image of the source/drain interconnect structure 226 as a result of, for example, slight oxidation or nitridation at the top surface of the first part 226a prior to deposition of the second part 226b.While the interface is shown as being located at the same level as the dielectric layer 210 (e.g., at a height or depth that is between the bottom surface and the top surface of the dielectric layer 210), the first part 226a and the second part 226b may be formed such that interface is located at another level in the semiconductor device 200 such as at the same level as the ESL 208, among other examples. The location of the interface between the first part 226a and the second part 226b may be based on a height of the source/drain interconnect structure 226, a width of the source/drain interconnect structure 226, an aspect ratio of the source/drain interconnect structure 226, a type of material that is used to form the first part 226a, a type of material that is used to form the second part 226b, and/or another factor.

In some implementations, the interface between the first part 224a and the second part 224b of the gate interconnect structure 224, and the interface between the first part 226a and the second part 226b of the source/drain interconnect structure 226, are located at the same height or the same vertical positions in the semiconductor device 200. In some implementations, the interface between the first part 224a and the second part 224b of the gate interconnect structure 224, and the interface between the first part 226a and the second part 226b of the source/drain interconnect structure 226, may be located at different heights or at different vertical positions in the semiconductor device 200. In some implementations, the height or vertical position of the interface between the first part 226a and the second part 226b of the source/drain interconnect structure 226 is greater than the height or vertical position of the interface between the first part 224a and the second part 224b of the gate interconnect structure 224. In some implementations, the height or vertical position of the interface between the first part 224a and the second part 224b of the gate interconnect structure 224 is greater than height or vertical position of the interface between the first part 226a and the second part 226b of the source/drain interconnect structure 226. In some implementations, the difference between the height or vertical position of the interface between the first part 226a and the second part 226b of the source/drain interconnect structure 226 and the height or vertical position of the interface between the first part 224a and the second part 224b of the gate interconnect structure 224 is in a range of approximately 2 nanometers to approximately 15 nanometers. However, other values for the difference are within the scope of the present disclosure.

The formation of the first part 226a and the second part 226b by respective and separate deposition operations further enables the first part 226a and the second part 226b to be formed of different conductive materials or different conductive material compositions including one or more conductive materials. For example, the first part 226a may include a first conductive material composition including one or more first conductive materials, the second part 226b may include a second conductive material composition including one or more second conductive materials, where the first conductive material composition and the second conductive material composition are different material compositions. This enables further flexibility in the semiconductor processes of forming the source/drain interconnect structure 226 and enables the formation of more complex and higher performance source/drain interconnect structures 226. Although, the first part 226a and the second part 226b being formed of the same material or same material composition is within the scope of the present disclosure. In some implementations, the first part 226a includes a conductive material such as tungsten (W), ruthenium (Ru), molybdenum (Mo), cobalt (Co), copper (Cu), another conductive material, a conductive material composition of one or more of the preceding conductive materials, or a combination thereof. In some implementations, the second part 226b includes a conductive material such as tungsten (W), ruthenium (Ru), molybdenum (Mo), cobalt (Co), copper (Cu), aluminum (Al), titanium (Ti), titanium nitride (TiN), another conductive material, a conductive material composition of one or more of the preceding conductive materials, or a combination thereof.

In some implementations, the grain size of the material of the first part 226a and the grain size of the material of the second part 226b are approximately the same grain size. In some implementations, the grain size of the material of the first part 226a and the grain size of the material of the second part 226b are different grain sizes. For example, the grain size of the material of the first part 226a may be greater than the grain size of the material of the second part 226b.As another example, the grain size of the material of the second part 226b may be greater than the grain size of the material of the first part 226a.

As indicated above, FIG. 2 is provided as an example. Other examples may differ from what is described with regard to FIG. 2.

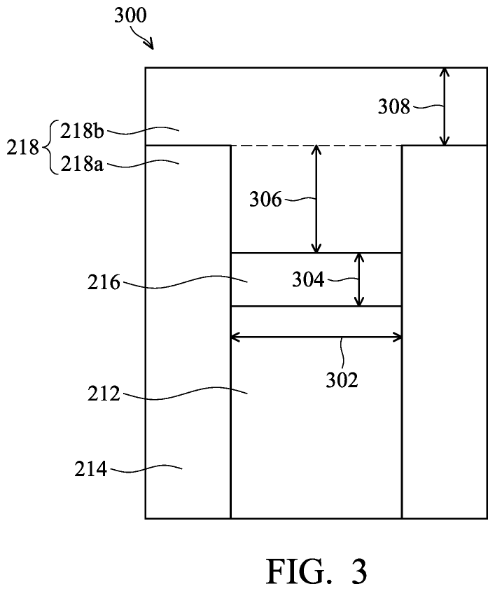

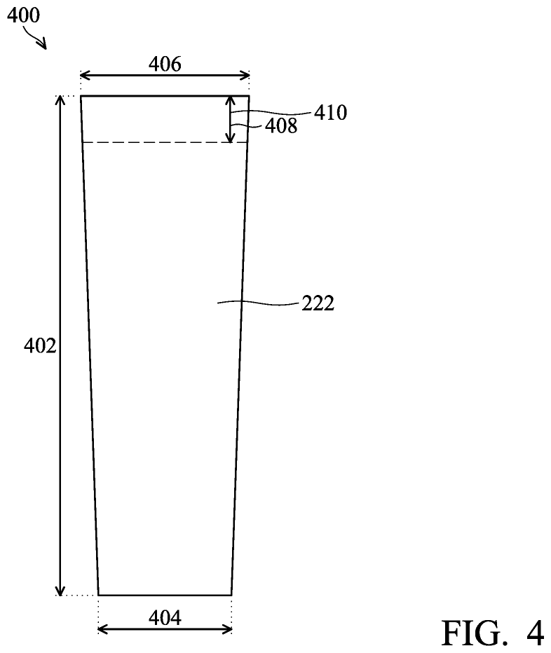

FIG. 3 is a diagram of an example implementation 300 of semiconductor structures described herein. The example implementation 300 includes various dimensions and/or parameters of a metal gate structure 212, of a plurality of sidewall spacers 214, of a metal capping layer 216, and of a dielectric capping layer 218 included in the semiconductor device 200.

As shown in FIG. 3, an example dimension 302 includes a width of the metal gate structure 212. In some implementations, the width of the metal gate structure 212 is included in a range of approximately 2 nanometers to approximately 50 nanometers to provide sufficient transistor channel control while enabling transistors to be densely integrated into the semiconductor device 200. However, other values for the width of the metal gate structure 212 are within the scope of the present disclosure. In some implementations, an aspect ratio between the width of the metal gate structure 212 and a height of the metal gate structure 212 is included in a range of approximately 1:1 to approximately 1:3 to provide sufficient transistor channel control while enabling transistors to be densely integrated into the semiconductor device 200. However, other values for the ratio are within the scope of the present disclosure.

As further shown in FIG. 3, an example dimension 304 includes a thickness of the metal capping layer 216. In some implementations, the thickness of the metal capping layer 216 is included in a range of approximately 1 nanometer to approximately 10 nanometers to achieve continuity and uniformity for the metal capping layer 216, to provide sufficient protection of the metal gate structure 212, and/or to achieve a sufficiently low contact resistance between the metal gate structure 212 and the gate interconnect structure 224. However, other values of the thickness of the metal capping layer are within the scope of the present disclosure.

As further shown in FIG. 3, and example dimension 306 includes a thickness of the first portion 218a of the dielectric capping layer 218. In some implementations, the thickness of the first portion 218a is included in a range of approximately 1 nanometer to approximately 50 nanometers such that the height of the first portion 218a is approximately equal to the height of the top surfaces of the sidewall spacers 214. However, other values for the thickness of the first portion are within the scope of the present disclosure.

As further shown in FIG. 3, and example dimension 308 includes a thickness of the second portion 218b of the dielectric capping layer 218. In some implementations, the thickness of the second portion 218b is included in a range of approximately 1 nanometer to approximately 30 nanometers such that the overall thickness of the dielectric capping layer 218 provides sufficient protection for the metal gate structure 212 and/or the metal capping layer 216. However, other values for the thickness of the first portion are within the scope of the present disclosure.

As indicated above, FIG. 3 is provided as examples. Other examples may differ from what is described with regard to FIG. 3.

FIG. 4 is a diagram of an example implementation 400 of a semiconductor structure described herein. The example implementation 400 includes various dimensions and/or parameters of a metal source/drain contact 222 included in the semiconductor device 200.

As shown in FIG. 4, an example dimension 402 includes a thickness or height of the metal source/drain contact 222. In some implementations, the thickness or height of the metal source/drain contact 222 is included in a range of approximately 10 nanometers to approximately 80 nanometers to connect the metal source/drain contact 222 to an associated source/drain region 220 and such that a height of a top surface of the metal source/drain contact 222 and a height of a top surface of an associated dielectric capping layer 218 included in the semiconductor device 200 are approximately equal. However, other values for the thickness or height of the metal source/drain contact 222 are within the scope of the present disclosure.

As further shown in FIG. 4, an example dimension 404 includes a bottom width of the metal source/drain contact 222. In some implementations, the bottom width of the metal source/drain contact 222 is included in a range of approximately 10 nanometers to approximately 25 nanometers to provide sufficient contact area between the metal source/drain contact 222 and an associated source/drain region 220 of the semiconductor device 200 for contact resistance performance while enabling increased transistor integration in the semiconductor device 200. However, other values for the bottom width of the metal source/drain contact 222 are within the scope of the present disclosure.

As further shown in FIG. 4, an example dimension 406 includes a top width of the metal source/drain contact 222. In some implementations, the top width of the metal source/drain contact 222 is included in a range of approximately 11 nanometers to approximately 27 nanometers to provide sufficient contact area between the metal source/drain contact 222 and an associated source/drain interconnect structure 226 for contact resistance performance while enabling increased transistor integration in the semiconductor device 200. However, other values for the top width of the metal source/drain contact 222 are within the scope of the present disclosure.

In some implementations, an aspect ratio between a width of the metal source/drain contact 222 (e.g., the bottom width or the top width) and the thickness or height of the metal source/drain contact 222 is included in a range of approximately 1:1 to approximately 1:3 to enable increased transistor integration in the semiconductor device 200 while achieving sufficient gap-filling performance for the metal source/drain contact 222. However, other values for the ratio are within the scope of the present disclosure.

As further shown in FIG. 4, an example dimension 408 includes a depth of a recess 410 included in the metal source/drain contact 222 (e.g., included in a top portion of the metal source/drain contact 222). The recess 410 may be included in the top portion of the metal source/drain contact 222 to provide increased surface area for connection between the metal source/drain contact 222 and an associated source/drain interconnect structure 226. In some implementations, the depth of the recess 410 is included in a range of approximately 0.5 nanometers to approximately 3 nanometers to provide sufficient surface contact area for the associated source/drain interconnect structure 226 while minimizing damage to the metal source/drain contact 222. However, other values for the depth are within the scope of the present disclosure.

As indicated above, FIG. 4 is provided as examples. Other examples may differ from what is described with regard to FIG. 4.

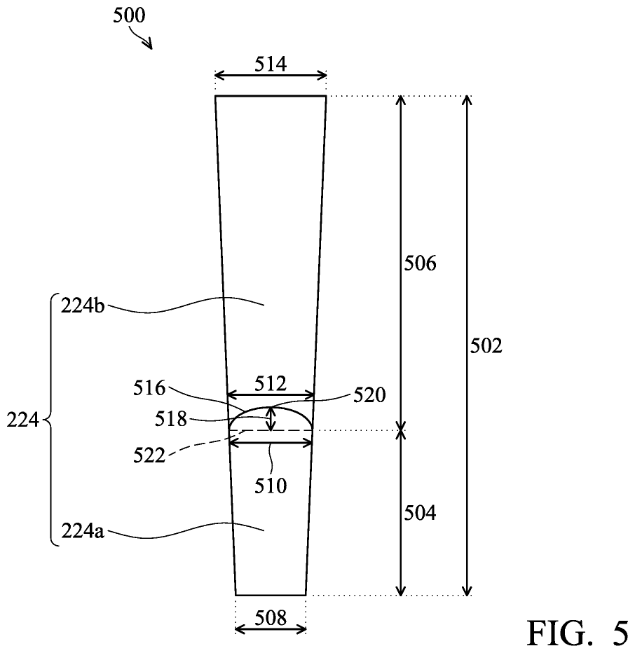

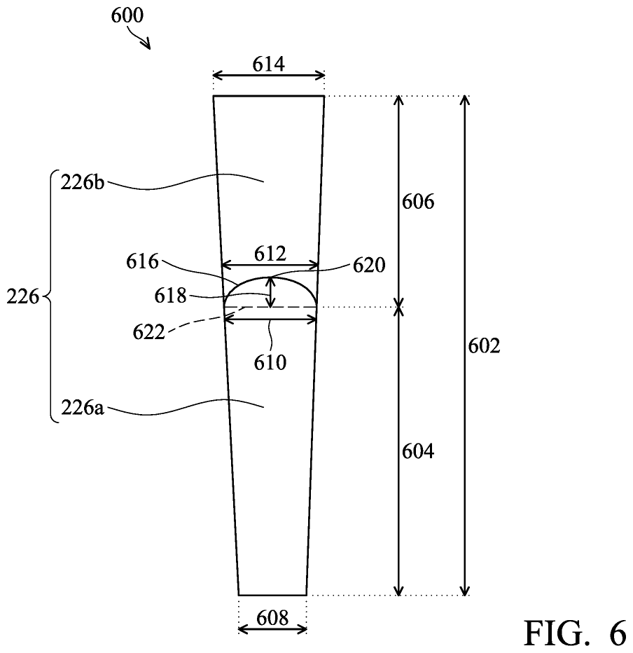

FIG. 5 is a diagram of an example implementation 500 of a semiconductor structure described herein. The example implementation 500 includes various dimensions and/or parameters of a gate interconnect structure 224 included in the semiconductor device 200. In particular, the example implementation 500 includes various dimensions and/or parameters of a two-part gate interconnect structure 224 described herein, including a first part 224a and a second part 224b.

As shown in FIG. 5, an example dimension 502 includes an overall thickness or height of the gate interconnect structure 224. In some implementations, the overall thickness or height of the gate interconnect structure 224 is included in a range of approximately 10 nanometers to approximately 80 nanometers based on the thickness of the ESL 208, the thickness of the dielectric layer 210, whether the gate interconnect structure is connected directly to a metal gate structure 212 or by a metal capping layer 216, and/or based on other parameters. However, other values for the overall thickness or height of the gate interconnect structure 224 are within the scope of the present disclosure.

As further shown in FIG. 5, an example dimension 504 includes a thickness or height of the first part 224a of the gate interconnect structure 224. In some implementations, the thickness or height of the first part 224a of the gate interconnect structure 224 is included in a range of approximately 5 nanometers to approximately 40 nanometers. In some implementations, the thickness or height of the first part 224a of the gate interconnect structure 224 is included in a range of approximately 5 nanometers to approximately 20 nanometers. In some implementations, the thickness or height of the first part 224a of the gate interconnect structure 224 is included in a range of approximately 21 nanometers to approximately 40 nanometers. The thickness or height of the first part 224a of the gate interconnect structure 224 may be configured in one or more of these ranges may provide sufficient defect migration and/or removal, as described herein. However, other values for the thickness or height of the first part 224a of the gate interconnect structure 224 are within the scope of the present disclosure.

As further shown in FIG. 5, an example dimension 506 includes a thickness or height of the second part 224b of the gate interconnect structure 224. In some implementations, the thickness or height of the second part 224b of the gate interconnect structure 224 is included in a range of approximately 5 nanometers to approximately 40 nanometers to provide sufficient defect migration and/or removal, as described herein. However, other values for the thickness or height of the second part 224b of the gate interconnect structure 224 are within the scope of the present disclosure.

As further shown in FIG. 5, an example dimension 508 includes a bottom width of the first part 224a of the gate interconnect structure 224 (which also corresponds to the bottom width of the gate interconnect structure 224). In some implementations, the bottom width of the first part 224a of the gate interconnect structure 224 is included in a range of approximately 2 nanometers to approximately 18 nanometers. In some implementations, the bottom width of the of the first part 224a of the gate interconnect structure 224 is included in a range of approximately 2 nanometers to approximately 6 nanometers. In some implementations, the bottom width of the of the first part 224a of the gate interconnect structure 224 is included in a range of approximately 8 nanometers to approximately 18 nanometers. The bottom width of the first part 224a of the gate interconnect structure 224 may be included in one or more of these ranges to provide sufficient contact area between the gate interconnect structure 224 and an associated metal gate structure 212 (or metal capping layer 216) of the semiconductor device 200 for contact resistance performance while enabling increased transistor integration in the semiconductor device 200. However, other values for the bottom width of the first part 224a of the gate interconnect structure 224 are within the scope of the present disclosure.

As further shown in FIG. 5, an example dimension 510 includes a top width of the first part 224a of the gate interconnect structure 224. In some implementations, the top width of the of the first part 224a of the gate interconnect structure 224 is included in a range of approximately 10 nanometers to approximately 20 nanometers based on the height or thickness of the first part 224a (e.g., which corresponds to the example dimension 504) and the taper of the gate interconnect structure 224. However, other values for the top width of the first part 224a of the gate interconnect structure 224 are within the scope of the present disclosure.

As further shown in FIG. 5, an example dimension 512 includes a bottom width of the second part 224b of the gate interconnect structure 224. In some implementations, the bottom width of the of the second part 224b of the gate interconnect structure 224 is included in a range of approximately 10 nanometers to approximately 20 nanometers based on the height or thickness of the first part 224a (e.g., which corresponds to the example dimension 504) and the taper of the gate interconnect structure 224. However, other values for the bottom width of the second part 224b of the gate interconnect structure 224 are within the scope of the present disclosure.

As further shown in FIG. 5, an example dimension 514 includes a top width of the second part 224b of the gate interconnect structure 224. In some implementations, the top width of the of the second part 224b of the gate interconnect structure 224 is included in a range of approximately 10 nanometers to approximately 20 nanometers based on the overall height of the gate interconnect structure 224 (e.g., which corresponds to the example dimension 502) and the taper of the gate interconnect structure 224. However, other values for the top width of the second part 224b of the gate interconnect structure 224 are within the scope of the present disclosure.

As further shown in FIG. 5, an interface 516 is included between the first part 224a of the gate interconnect structure 224 and the second part 224b of the gate interconnect structure 224. The interface 516 is curved (or approximately curved) and/or otherwise non-straight-lined, which results from the two-step anneal techniques described herein to remove defects (e.g., voids, gaps, cracks, sidewall slits, discontinuities, and/or other types of defects) from the first part 224a and from the second part 224b during formation of the gate interconnect structure 224. In particular, an annealing operation is performed on the first part 224a to drive out and/or otherwise remove defects from the first part 224a. The annealing operation performed on the first part 224a results in the formation of the curved top surface of the first part 224a due to the formation of a meniscus at the top surface of the first part 224a. The bottom surface of the second part 224b is then formed thereon and takes on the form of (or conforms to) the curved top surface of the first part 224a, thereby resulting in the curved interface 516.

As further shown in FIG. 5, an example dimension 518 includes a distance between a center 520 of the curve of the interface 516 and a base 522 of the curve of the interface 516. The example dimension 518 may also be referred to as a sagitta of the interface 516, which corresponds to a straight-line distance between the center (e.g., center 520) of a circular arc (e.g., the interface 516) to a location at the base (e.g., the base 522) of the circular arc that is approximately perpendicular to the base of the circular arc. In some implementations, the sagitta may be less than or greater than the radius of the curve or arc of the interface 516. In some implementations, the distance between a center 520 of the curve of the interface 516 and a base 522 of the curve of the interface 516 is included in a range of greater than 0 nanometers to approximately 3 nanometers as a result of the annealing operation that is performed for the first part 224a to remove defects from the first part 224a. However, other values for the distance are within the scope of the present disclosure.

As further shown in FIG. 5, the gate interconnect structure 224 is tapered between the top of the second part 224b and the bottom of the first part 224a. In some implementations, the gate interconnect structure 224 is tapered between the top of the second part 224b and the bottom of the first part 224a in an approximately continuous and uniform manner, as illustrated in the example in FIG. 5. However, in other implementations, the gate interconnect structure 224 is tapered between the top of the second part 224b and the bottom of the first part 224a in a non-linear and/or a non-uniform manner. The taper may include a curved taper, a tiered taper, or another type of non-linear and/or non-uniform taper. A non-linear and/or non-uniform taper may occur, for example, where the recess in which the gate interconnect structure 224 is to be formed is etched through a plurality of different layers having different etch selectivity and/or different etch rates.

In some implementations, an aspect ratio between a width of the gate interconnect structure 224 (e.g., the bottom width of the gate interconnect structure 224, which corresponds to the bottom width of the first part 224a and the example dimension 508, or the top width of the gate interconnect structure 224, which corresponds to the top width of the second part 224b and the example dimension 514) and the overall thickness or height of the gate interconnect structure 224 (e.g., which corresponds to the example dimension 502) is included in a range of approximately 1:5.5 to approximately 1:8 to enable increased transistor integration in the semiconductor device 200 while achieving sufficient gap-filling performance for the gate interconnect structure 224. However, other values for the aspect ratio are within the scope of the present disclosure.

In some implementations, a ratio between a width of the first part 224a of the gate interconnect structure 224 (e.g., the bottom width corresponding to the example dimension 508 or the top width corresponding to the example dimension 510) and a width of the second part 224b of the gate interconnect structure 224 (e.g., the bottom width corresponding to the example dimension 512 or the top width corresponding to the example dimension 514) is included in a range of approximately 1:1 to approximately 1:2 based on the respective heights of the first part 224a and the second part 224b and the taper of the gate interconnect structure 224. However, other values for the ratio are within the scope of the present disclosure.

In some implementations, a ratio between a volume or area occupied by the first part 224a of the gate interconnect structure 224 and a volume or area occupied by the second part 224b of the gate interconnect structure 224 is included in a range of approximately 1:2 to approximately 1:4 based on the respective heights of the first part 224a and the second part 224b and the taper of the gate interconnect structure 224. However, other values for the ratio are within the scope of the present disclosure.

As indicated above, FIG. 5 is provided as examples. Other examples may differ from what is described with regard to FIG. 5.

FIG. 6 is a diagram of an example implementation 600 of a semiconductor structure described herein. The example implementation 600 includes various dimensions and/or parameters of a source/drain interconnect structure 226 included in the semiconductor device 200. In particular, the example implementation 600 includes various dimensions and/or parameters of a two-part source/drain interconnect structure 226 described herein, including a first part 226a and a second part 226b.

As shown in FIG. 6, an example dimension 602 includes an overall thickness or height of the source/drain interconnect structure 226. In some implementations, the overall thickness or height of the source/drain interconnect structure 226 is included in a range of approximately 10 nanometers to approximately 80 nanometers based on the thickness of the ESL 208, the thickness of the dielectric layer 210, the height of an associated metal source/drain contact 222, and/or based on other parameters. However, other values for the overall thickness or height of the source/drain interconnect structure 226 are within the scope of the present disclosure.

As further shown in FIG. 6, an example dimension 604 includes a thickness or height of the first part 226a of the source/drain interconnect structure 226. In some implementations, the thickness or height of the first part 226a of the source/drain interconnect structure 226 is included in a range of approximately 5 nanometers to approximately 40 nanometers. In some implementations, the thickness or height of the first part 226a of the source/drain interconnect structure 226 is included in a range of approximately 5 nanometers to approximately 20 nanometers. In some implementations, the thickness or height of the first part 226a of the source/drain interconnect structure 226 is included in a range of approximately 21 nanometers to approximately 40 nanometers. The thickness or height of the first part 226a of the source/drain interconnect structure 226 may be configured in one or more of these ranges may provide sufficient defect migration and/or removal, as described herein. However, other values for the thickness or height of the first part 226a of the source/drain interconnect structure 226 are within the scope of the present disclosure.

As further shown in FIG. 6, an example dimension 606 includes a thickness or height of the second part 226b of the source/drain interconnect structure 226. In some implementations, the thickness or height of the second part 226b of the source/drain interconnect structure 226 is included in a range of approximately 5 nanometers to approximately 40 nanometers to provide sufficient defect migration and/or removal, as described herein. However, other values for the thickness or height of the second part 226b of the source/drain interconnect structure 226 are within the scope of the present disclosure.

As further shown in FIG. 6, an example dimension 608 includes a bottom width of the first part 226a of the source/drain interconnect structure 226 (which also corresponds to the bottom width of the source/drain interconnect structure 226). In some implementations, the bottom width of the of the first part 226a of the source/drain interconnect structure 226 is included in a range of approximately 2 nanometers to approximately 18 nanometers. In some implementations, the bottom width of the of the first part 226a of the source/drain interconnect structure 226 is included in a range of approximately 2 nanometers to approximately 6 nanometers. In some implementations, the bottom width of the of the first part 226a of the source/drain interconnect structure 226 is included in a range of approximately 8 nanometers to approximately 18 nanometers. The bottom width of the first part 226a of the source/drain interconnect structure 226 may be included in one or more of these ranges to provide sufficient contact area between the source/drain interconnect structure 226 and an associated metal source/drain contact 222 of the semiconductor device 200 for contact resistance performance while enabling increased transistor integration in the semiconductor device 200. However, other values for the bottom width of the first part 226a of the source/drain interconnect structure 226 are within the scope of the present disclosure.

As further shown in FIG. 6, an example dimension 610 includes a top width of the first part 226a of the source/drain interconnect structure 226. In some implementations, the top width of the of the first part 226a of the source/drain interconnect structure 226 is included in a range of approximately 10 nanometers to approximately 20 nanometers based on the height or thickness of the first part 226a (e.g., which corresponds to the example dimension 504) and the taper of the source/drain interconnect structure 226. However, other values for the top width of the first part 226a of the source/drain interconnect structure 226 are within the scope of the present disclosure.

As further shown in FIG. 6, an example dimension 612 includes a bottom width of the second part 226b of the source/drain interconnect structure 226. In some implementations, the bottom width of the of the second part 226b of the source/drain interconnect structure 226 is included in a range of approximately 10 nanometers to approximately 20 nanometers based on the height or thickness of the first part 226a (e.g., which corresponds to the example dimension 604) and the taper of the source/drain interconnect structure 226. However, other values for the bottom width of the second part 226b of the source/drain interconnect structure 226 are within the scope of the present disclosure.

As further shown in FIG. 6, an example dimension 614 includes a top width of the second part 226b of the source/drain interconnect structure 226. In some implementations, the top width of the of the second part 226b of the source/drain interconnect structure 226 is included in a range of approximately 10 nanometers to approximately 20 nanometers based on the overall height of the source/drain interconnect structure 226 (e.g., which corresponds to the example dimension 602) and the taper of the source/drain interconnect structure 226. However, other values for the top width of the second part 226b of the source/drain interconnect structure 226 are within the scope of the present disclosure.

As further shown in FIG. 6, an interface 616 is included between the first part 226a of the source/drain interconnect structure 226 and the second part 226b of the source/drain interconnect structure 226. The interface 616 is curved (or approximately curved) and/or otherwise non-straight-lined, which results from the two-step anneal techniques described herein to remove defects (e.g., voids, gaps, cracks, sidewall slits, discontinuities, and/or other types of defects) from the first part 226a and from the second part 226b during formation of the source/drain interconnect structure 226. In particular, an annealing operation is performed on the first part 226a to drive out and/or otherwise remove defects from the first part 226a. The annealing operation performed on the first part 226a results in the formation of the curved top surface of the first part 226a due to the formation of a meniscus at the top surface of the first part 226a. The bottom surface of the second part 226b is then formed thereon and takes on the form of (or conforms to) the curved top surface of the first part 226a, thereby resulting in the curved interface 616.

As further shown in FIG. 6, an example dimension 618 includes a distance between a center 620 of the curve of the interface 616 and a base 622 of the curve of the interface 616. The example dimension 618 may also be referred to as a sagitta of the interface 616, which corresponds to a straight-line distance between the center (e.g., center 620) of a circular arc (e.g., the interface 616) to a location at the base (e.g., the base 622) of the circular arc that is approximately perpendicular to the base of the circular arc. In some implementations, the sagitta may be less than or greater than the radius of the curve or arc of the interface 616. In some implementations, the distance between a center 620 of the curve of the interface 616 and a base 622 of the curve of the interface 616 is included in a range of greater than 0 nanometers to approximately 3 nanometers as a result of the annealing operation that is performed for the first part 226a to remove defects from the first part 226a. However, other values for the distance are within the scope of the present disclosure.

As further shown in FIG. 6, the source/drain interconnect structure 226 is tapered between the top of the second part 226b and the bottom of the first part 226a. In some implementations, the source/drain interconnect structure 226 is tapered between the top of the second part 226b and the bottom of the first part 226a in an approximately continuous and uniform manner, as illustrated in the example in FIG. 6. However, in other implementations, the source/drain interconnect structure 226 is tapered between the top of the second part 226b and the bottom of the first part 226a in a non-linear and/or a non-uniform manner. The taper may include a curved taper, a tiered taper, or another type of non-linear and/or non-uniform taper. A non-linear and/or non-uniform taper may occur, for example, where the recess in which the source/drain interconnect structure 226 is to be formed is etched through a plurality of different layers having different etch selectivity and/or different etch rates.

In some implementations, an aspect ratio between a width of the source/drain interconnect structure 226 (e.g., the bottom width of the source/drain interconnect structure 226, which corresponds to the bottom width of the first part 226a and the example dimension 608, or the top width of the source/drain interconnect structure 226, which corresponds to the top width of the second part 226b and the example dimension 614) and the overall thickness or height of the source/drain interconnect structure 226 (e.g., which corresponds to the example dimension 602) is included in a range of approximately 1:3.5 to approximately 1:5 to enable increased transistor integration in the semiconductor device 200 while achieving sufficient gap-filling performance for the source/drain interconnect structure 226. However, other values for the aspect ratio are within the scope of the present disclosure.

In some implementations, a ratio between a width of the first part 226a of the source/drain interconnect structure 226 (e.g., the bottom width corresponding to the example dimension 608 or the top width corresponding to the example dimension 610) and a width of the second part 226b of the source/drain interconnect structure 226 (e.g., the bottom width corresponding to the example dimension 612 or the top width corresponding to the example dimension 614) is included in a range of approximately 1:1 to approximately 1:2 based on the respective heights of the first part 226a and the second part 226b and the taper of the source/drain interconnect structure 226. However, other values for the ratio are within the scope of the present disclosure.

In some implementations, a ratio between a volume or area occupied by the first part 226a of the source/drain interconnect structure 226 and a volume or area occupied by the second part 226b of the source/drain interconnect structure 226 is included in a range of approximately 1:1 to approximately 1:3 based on the respective heights of the first part 226a and the second part 226b and the taper of the source/drain interconnect structure 226. However, other values for the ratio are within the scope of the present disclosure.

As indicated above, FIG. 6 is provided as examples. Other examples may differ from what is described with regard to FIG. 6.

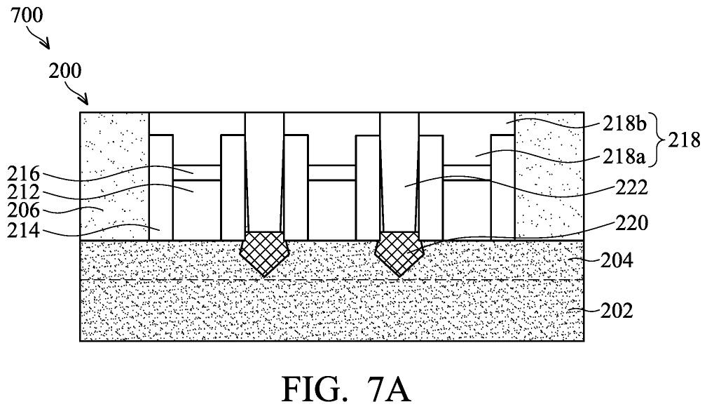

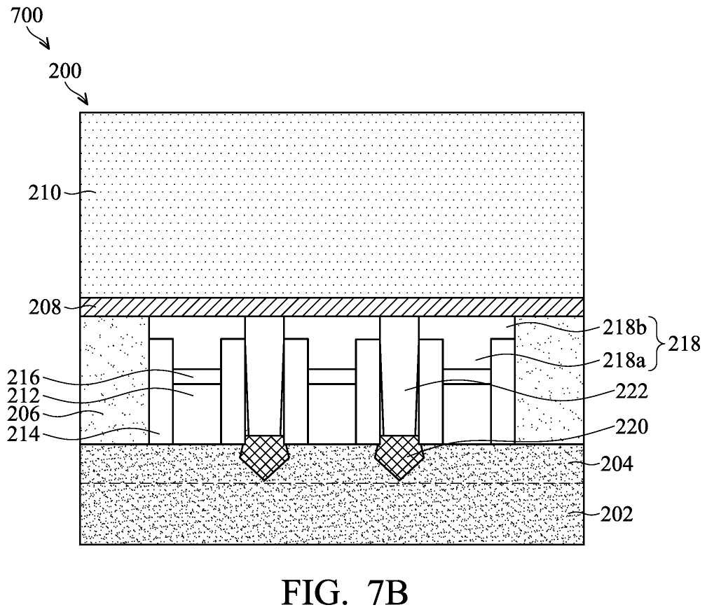

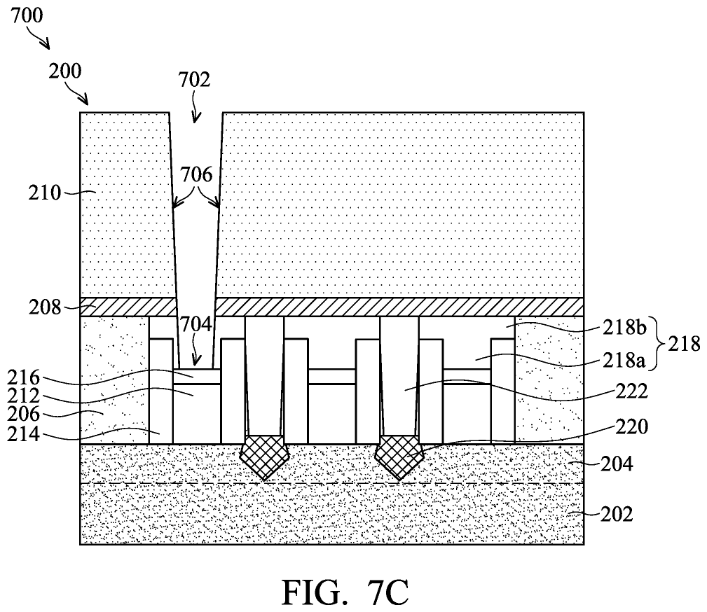

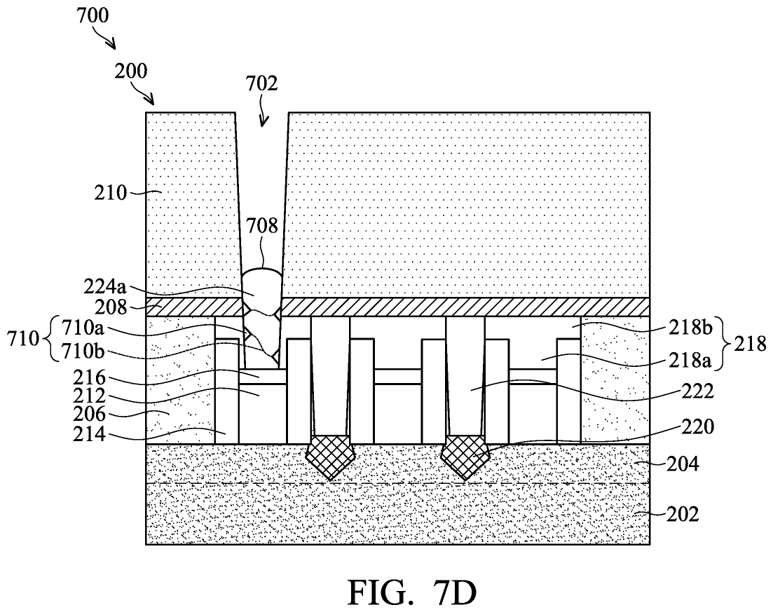

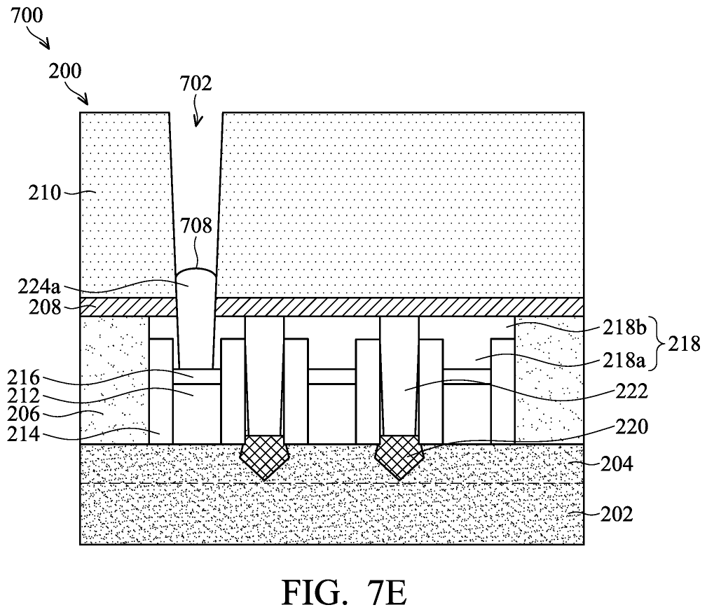

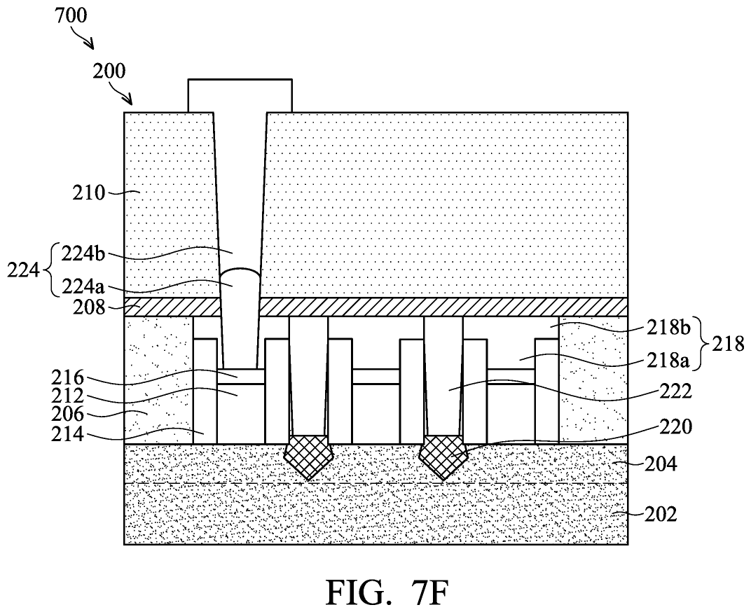

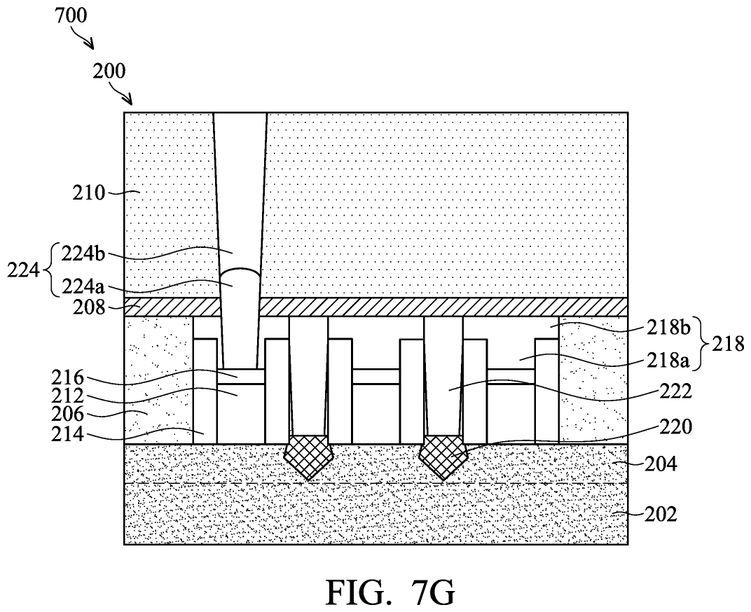

FIGS. 7A-7G are diagrams of an example implementation 700 described herein. The example implementation 700 includes an example of forming a two-part interconnect structure such as the gate interconnect structure 224 including the first part 224a and the second part 224b included in the semiconductor device 200 illustrated in FIG. 2 and/or elsewhere herein. Turning to FIG. 7A, one or more operations may be performed to form the fin structure 204, the metal gate structures 212, the metal capping layers 216, the dielectric capping layers 218, the dielectric layer 206, and/or the metal source/drain contacts 222.

As shown in FIG. 7B, the ESL 208 is formed on the semiconductor device 200, and the dielectric layer 210 is formed over and/or on the ESL 208. In some implementations, a deposition tool 102 deposits the ESL 208 and the dielectric layer 210 by a CVD, ALD, PVD, and/or another deposition technique.

As shown in FIG. 7C, an opening (or a recess) 702 is formed in the dielectric layer 210 and in the ESL 208. In particular, the opening 702 is formed in the dielectric layer 210, in the ESL 208, in a dielectric capping layer 218, and to conductive layer such as a metal capping layer 216 over and/or on a metal gate structure 212. In some implementations, the opening 702 is formed directly to the metal gate structure 212. As shown in FIG. 7C, the opening 702 includes a bottom surface 704 (which corresponds to the metal capping layer 216 or the metal gate structure 212) and sidewalls 706 (which correspond to the ESL 208, the dielectric layer 210, and the dielectric capping layer 218).

In some implementations, a pattern in a photoresist layer is used to etch the dielectric layer 210, the ESL 208, and the dielectric capping layer 218 to form the opening 702. In these implementations, the deposition tool 102 forms the photoresist layer on the dielectric layer 210. The exposure tool 104 exposes the photoresist layer to a radiation source to pattern the photoresist layer. The developer tool 106 develops and removes portions of the photoresist layer to expose the pattern. The etch tool 108 etches the dielectric layer 210, the ESL 208, and/or the dielectric capping layer 218 based on the pattern to form the opening 702. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for etching the opening 702 based on a pattern.

As shown in FIG. 7D, a first portion of the opening 702 is filled with a conductive material (or a conductive material composition) to form the first part 224a of the gate interconnect structure 224. In particular, the first part 224a is deposited over the conductive structure (e.g., the metal capping layer 216 or the metal cate structure 212) in the opening 702. In some implementations, the deposition tool 102 performs a PVD operation, a CVD operation, or another type of deposition operation to form the first part 224a of the gate interconnect structure 224 in the first portion of the opening 702. In some implementations, the plating tool 112 performs a plating operation such as an electroplating operation to form the first part 224a of the gate interconnect structure 224 in the first portion of the opening 702. In some implementations, the deposition tool 102 performs a deposition operation to deposit a seed layer in the opening 702 to promote adhesion of the first part 224a to the sidewalls 706, and the deposition tool 102 performs another deposition operation (or the plating tool 112) performs a plating operation to fill in the remaining portion of the first part 224a over the seed layer. A top surface 708 of the first part 224a of the gate interconnect structure 224 is convex (e.g., curved away from a bottom surface of the first part 224a) after performing the deposition operation.

As further shown in FIG. 7D, defects 710 may result in the first part 224a of the gate interconnect structure 224 from the formation of the first part 224a. The defects 710 may include, for example, sidewall voids 710a that form from embedded defects 710b aggregating at the sidewalls of the first part 224a. The sidewall voids 710a may continue to aggregate and in some cases may result in discontinuities or other types of defects in the first part 224a.

As shown in FIG. 7E, an annealing operation is subsequently performed on the semiconductor device 200 after the first part 224a of the gate interconnect structure 224 is formed. The annealing tool 114 may perform the annealing operation to remove the defects 710 from the first part 224a of the gate interconnect structure 224 prior to the opening 702 being fully filled the gate interconnect structure 224. In this way, the effectiveness of the annealing operation to remove the defects 710 is increased relative to performing the annealing operation to remove the defects 710 when the opening 702 is fully filled in the gate interconnect structure 224. As further shown in FIG. 7E, the top surface 708 of the first part 224a of the gate interconnect structure 224 is convex (e.g., curved away from a bottom surface of the first part 224a) after performing the annealing operation.

In some implementations, the annealing operation is performed using a combination of gases including nitrogen (N2), helium (He), and argon (Ar), the annealing operation is performed in a temperature range of approximately 200 degrees Celsius to approximately 450 degrees Celsius (e.g., facilitate and promote defect migration and removal in the first part 224a while minimizing damage to other areas or structures of the semiconductor device 200), and the annealing operation is performed at a vacuum pressure range of approximately 0.5 Tor to approximately 10 Tor (e.g. facilitate and promote defect migration and removal in the first part 224a while minimizing other material migrations in the semiconductor device 200 and minimizing damage to other areas or structures of the semiconductor device 200). In some implementations, the annealing operation is performed using a gas including hydrogen (H2), a temperature range of approximately 160 degrees Celsius to approximately 450 degrees Celsius (e.g., facilitate and promote defect migration and removal in the first part 224a while minimizing damage to other areas or structures of the semiconductor device 200), and a vacuum pressure range of approximately 0.5 Tor to approximately 10 Tor (e.g. facilitate and promote defect migration and removal in the first part 224a while minimizing other material migrations in the semiconductor device 200 and minimizing damage to other areas or structures of the semiconductor device 200). However, other processing parameters such as the gas, the temperature, and/or the vacuum pressure, among other examples, are within the scope of the present disclosure.

As shown in FIG. 7F, the remaining portion of the opening 702 is filled with a conductive material (or a conductive material composition) to form the second part 224b of the gate interconnect structure 224 in the opening 702. In particular, the second part 224b is deposited over the first part 224a in the opening 702. In some implementations, the conductive material (or the conductive material composition) of the second part 224b is the same conductive material (or the same conductive material composition) as the conductive material (or the conductive material composition) of the first part 224a of the gate interconnect structure 224. In some implementations, the conductive material (or the conductive material composition) of the second part 224b is different from the conductive material (or the conductive material composition) of the first part 224a of the gate interconnect structure 224.

In some implementations, the deposition tool 102 performs a PVD operation, a CVD operation, or another type of deposition operation to form the second part 224b of the gate interconnect structure 224 in the remaining portion of the opening 702. In some implementations, the plating tool 112 performs a plating operation such as an electroplating operation to form the second part 224b of the gate interconnect structure 224 in the remaining portion of the opening 702. In some implementations, the deposition tool 102 performs a deposition operation to deposit a seed layer in the opening 702 to promote adhesion of the second part 224b to the sidewalls 706, and the deposition tool 102 performs another deposition operation (or the plating tool 112) performs a plating operation to fill in the remaining portion of the second part 224b over the seed layer.

As further shown in FIG. 7F, the opening 702 may be overfilled to ensure complete filling of the opening 702 with the gate interconnect structure 224. In some implementations, another annealing operation is performed for the semiconductor device 200 after forming the second part 224b in the opening 702. In this way, defects in the second part 224b may be removed after forming the second part 224b. As shown in FIG. 7G, a CMP operation is performed to planarize the gate interconnect structure 224.

As indicated above, FIGS. 7A-7G are provided as examples. Other examples may differ from what is described with regard to FIG. 7A-7G.

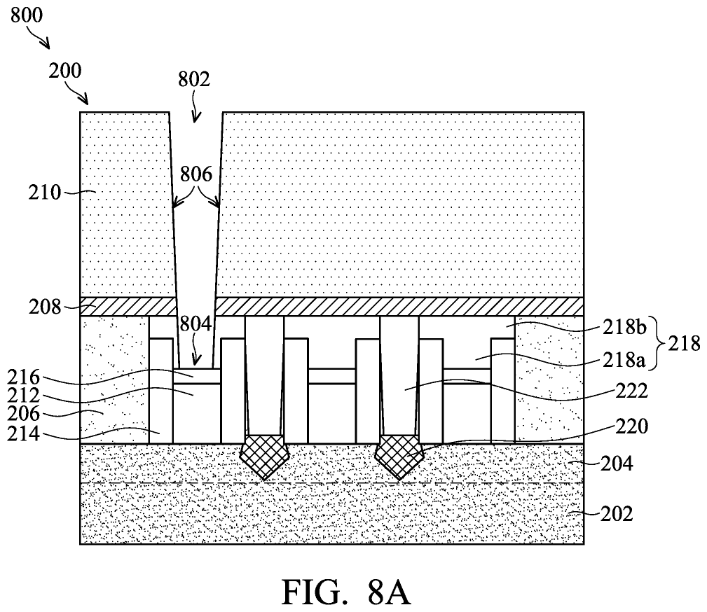

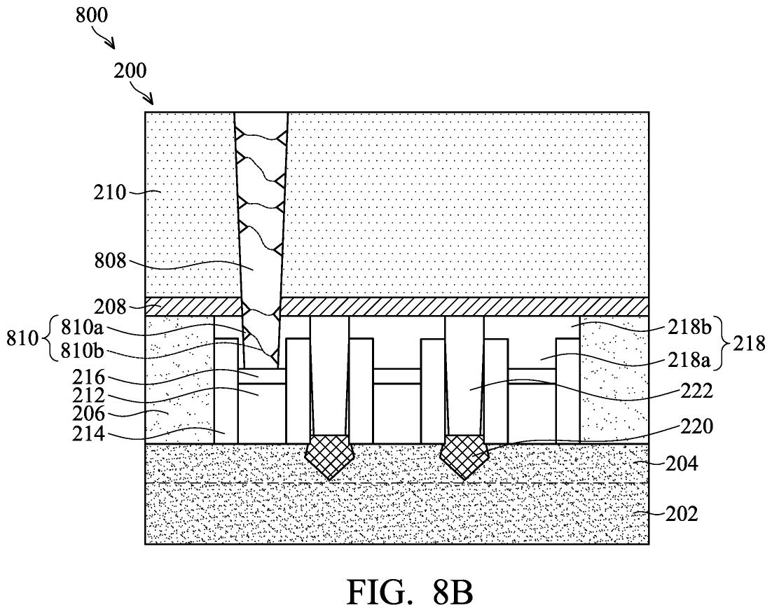

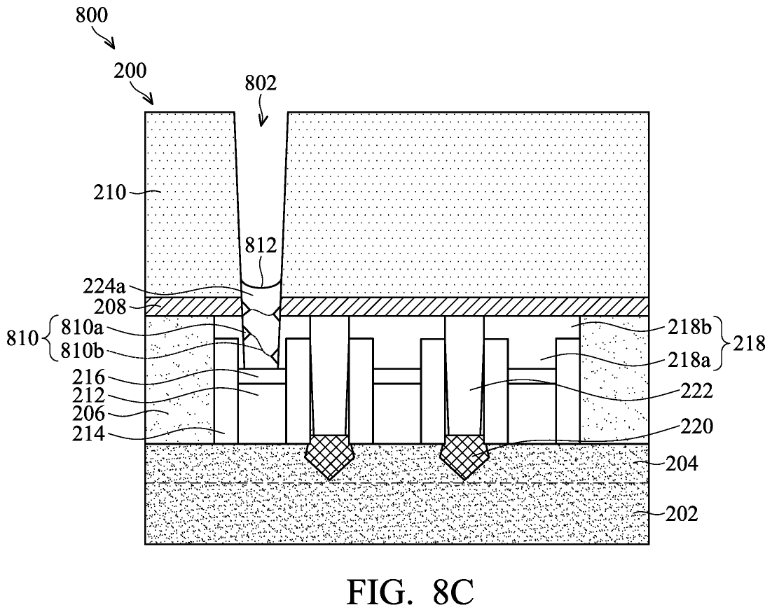

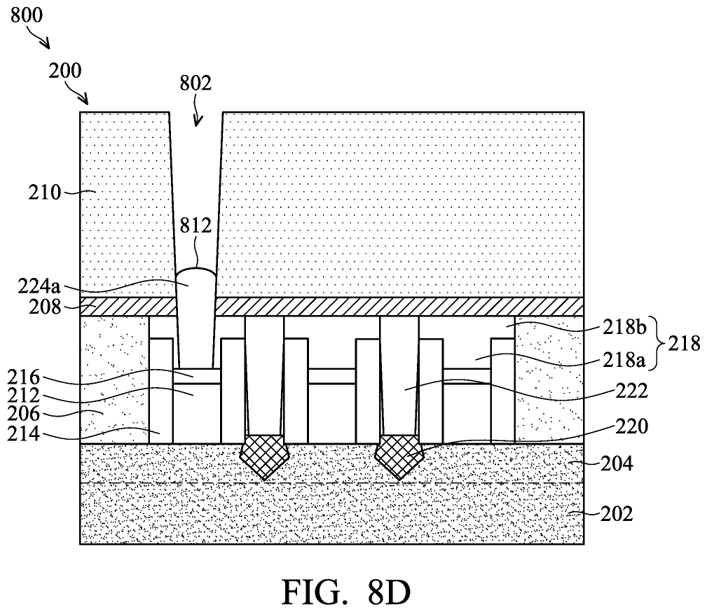

FIGS. 8A-8F are diagrams of an example implementation 800 described herein. The example implementation 800 includes another example of forming a two-part interconnect structure such as the gate interconnect structure 224 including the first part 224a and the second part 224b included in the semiconductor device 200 illustrated in FIG. 2 and/or elsewhere herein. Turning to FIG. 8A, one or more operations may be performed to form the fin structure 204, the metal gate structures 212, the metal capping layers 216, the dielectric capping layers 218, the dielectric layer 206, and/or the metal source/drain contacts 222. Moreover, one or more operations described in connection with FIGS. 7A-7G may be performed to form an opening (or recess) 802 above the metal gate structure 212. As shown in FIG. 8A, the opening 802 includes a bottom surface 804 and sidewalls 806.

As shown in FIG. 8B, the opening 802 (e.g., approximately the entire opening 802) is filled with a conductive material (or a conductive material composition) to form a sacrificial structure 808 for the gate interconnect structure 224 in the opening 802. In particular, the sacrificial structure 808 is deposited over the conductive structure (e.g., the metal capping layer 216 or the metal cate structure 212) in the opening 802. In some implementations, the deposition tool 102 performs a PVD operation, a CVD operation, or another type of deposition operation to form the sacrificial structure 808 in the opening 802. In some implementations, the plating tool 112 performs a plating operation such as an electroplating operation to form the sacrificial structure 808 in the opening 802. In some implementations, the deposition tool 102 performs a deposition operation to deposit a seed layer in the opening 802 to promote adhesion between the sacrificial structure 808 and the sidewalls 806 of the opening 802, and the deposition tool 102 performs another deposition operation (or the plating tool 112) performs a plating operation to fill in the remaining portion of the sacrificial structure 808 in the opening 802 over the seed layer.

The sacrificial structure 808 includes a layer of conductive material that is to be etched back in a subsequent etching operation to form the first part 224a of the gate interconnect structure 224 as opposed to the partial filling technique for the first part 224a described above in connection with FIGS. 7A-7G. This enables non-selective materials and/or deposition techniques to be used to form the sacrificial structure 808, as the sacrificial structure 808 is to be etched back in a subsequent etching operation.

As further shown in FIG. 8B, defects 810 may result in the sacrificial structure 808 from the formation of the sacrificial structure 808. The defects 810 may include, for example, sidewall voids 810a that form from embedded defects 810b aggregating at the sidewalls of the sacrificial structure 808. The sidewall voids 810a may continue to aggregate and in some cases may result in discontinuities or other types of defects in the sacrificial structure 808.

As shown in FIG. 8C, an etching operation (referred to as an etch back operation) is performed to remove a portion of the sacrificial structure 808 from the opening 802. For example, the etch tool 108 may perform the etching operation to remove the portion of the sacrificial structure 808 from the opening 802. The remaining portion of the sacrificial structure 808 in the opening 802 becomes the first part 224a of the gate interconnect structure 224. As further shown in FIG. 8C, a top surface 812 of the first part 224a of the gate interconnect structure 224 is concave (e.g., curved toward the bottom of the first part 224a) after the etching operation.

As shown in FIG. 8D, an annealing operation is performed on the semiconductor device 200 after the etching operation to form the first part 224a of the gate interconnect structure 224. The annealing tool 114 may perform the annealing operation to remove the defects 810 from the first part 224a of the gate interconnect structure 224 prior to the opening 802 being fully filled the gate interconnect structure 224. In this way, the effectiveness of the annealing operation to remove the defects 810 is increased relative to performing the annealing operation to remove the defects 810 when the opening 802 is fully filled in the gate interconnect structure 224 (or the sacrificial structure 808). As further shown in FIG. 8D, the top surface 812 of the first part 224a of the gate interconnect structure 224 is convex (e.g., curved away from the bottom of the first part 224a) after performing the annealing operation. The annealing operation may be performed using one or more (or various combinations) of the annealing operation parameters described above in connection with FIGS. 7A-7G.

As shown in FIGS. 8E and 8F respectively, the remaining portion of the opening 802 is filled with a conductive material (or a conductive material composition) to form the second part 224b of the gate interconnect structure 224 in the opening 802 and a CMP operation is performed to planarize the gate interconnect structure 224. In some implementations, another annealing operation is performed for the semiconductor device 200 after forming the second part 224b in the opening 802. In this way, defects in the second part 224b may be removed after forming the second part 224b.

As indicated above, FIGS. 8A-8F are provided as examples. Other examples may differ from what is described with regard to FIG. 8A-8F.

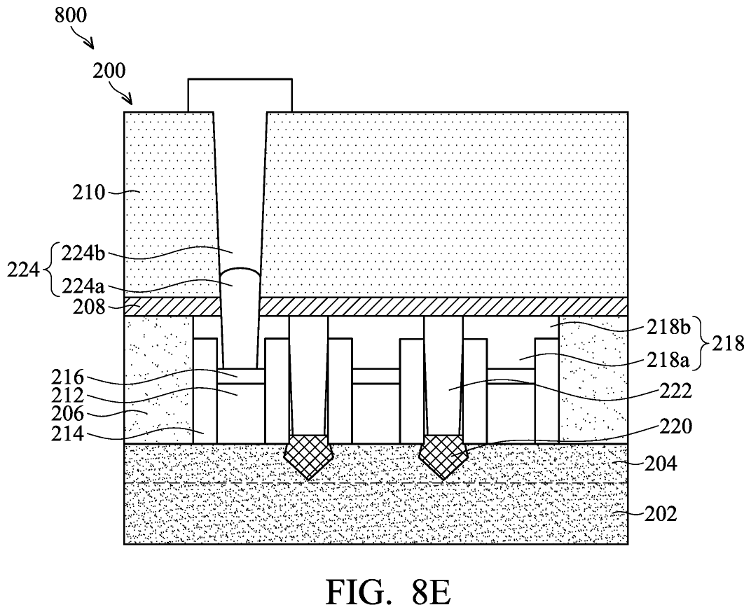

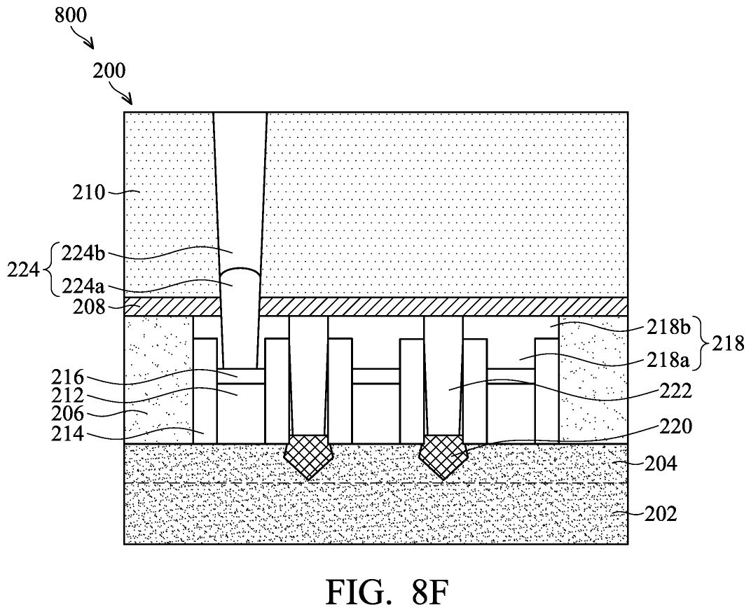

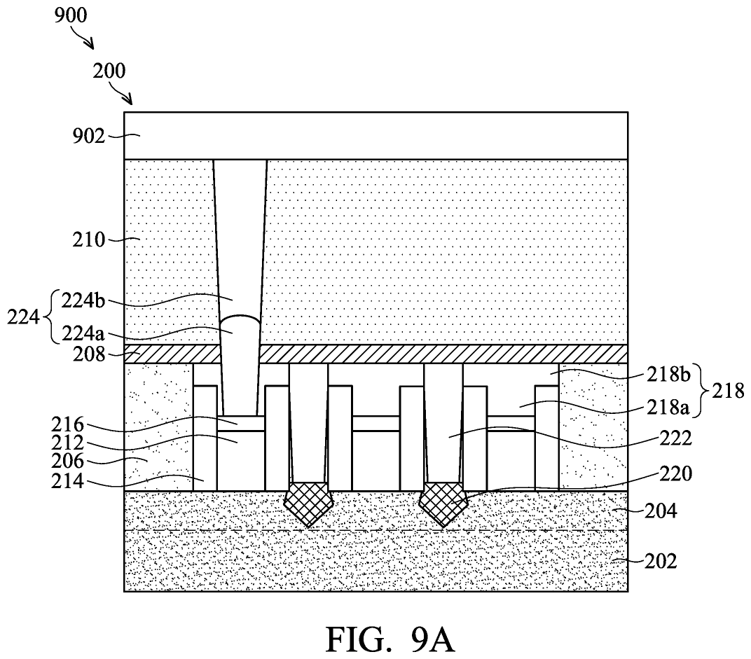

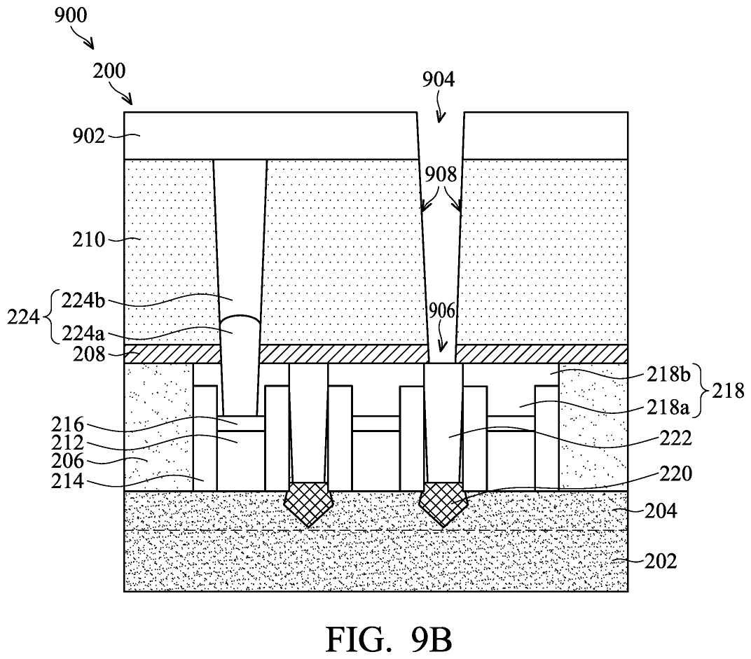

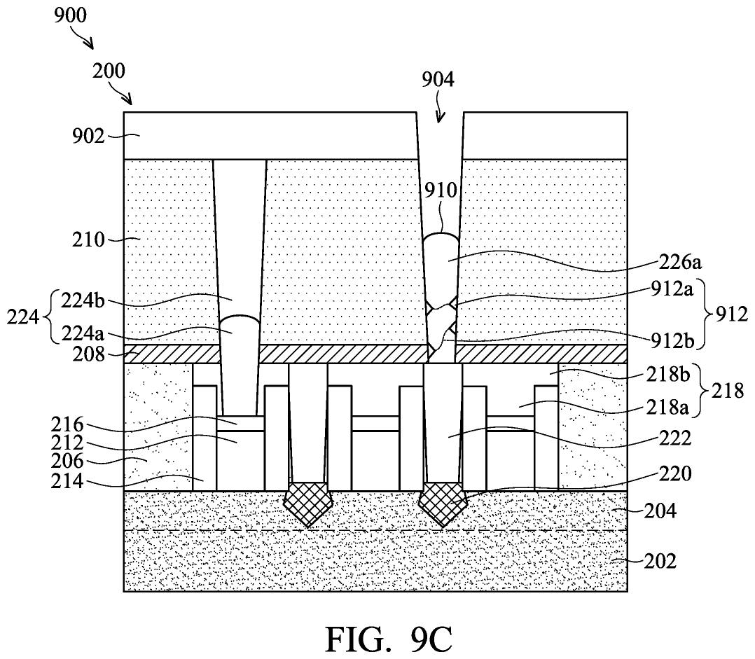

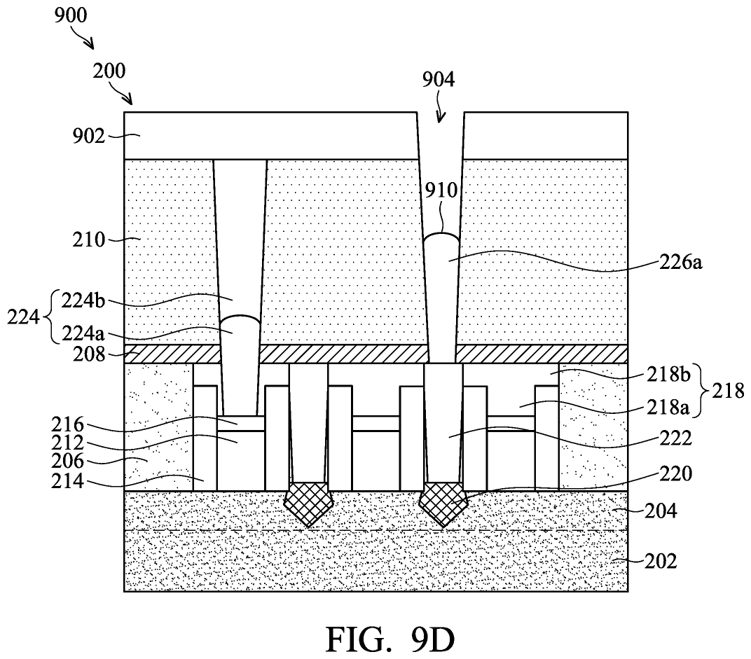

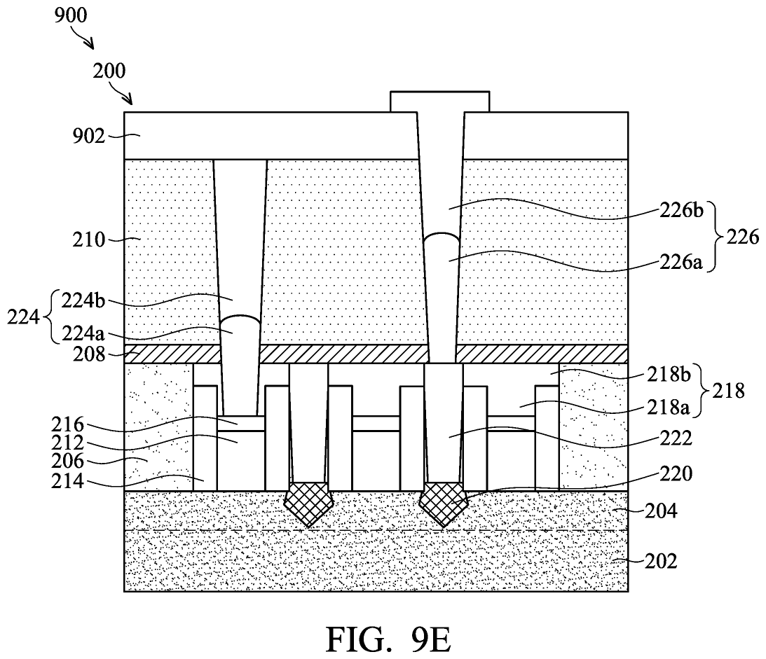

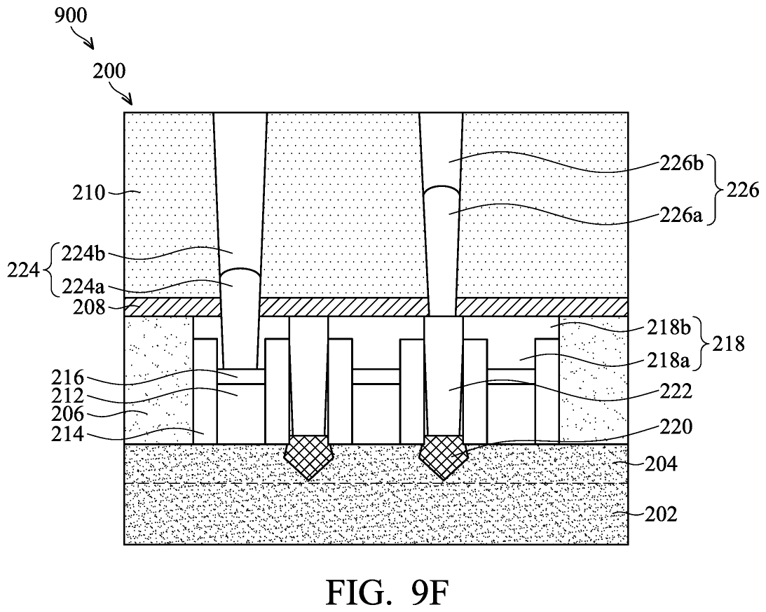

FIGS. 9A-9F are diagrams of an example implementation 900 described herein. The example implementation 900 includes an example of forming a two-part interconnect structure such as the source/drain interconnect structure 226 including the first part 226a and the second part 226b included in the semiconductor device 200 illustrated in FIG. 2 and/or elsewhere herein. Turning to FIG. 9A, one or more operations may be performed to form the fin structure 204, the metal gate structures 212, the metal capping layers 216, the dielectric capping layers 218, the dielectric layer 206, and/or the metal source/drain contacts 222. Moreover, one or more operations described in connection with FIGS. 7A-7G and/or FIGS. 8A-8F may be performed to form the ESL 208, the dielectric layer 210, and the gate interconnect structure 224 including the first part 224a and the second part 224b.

As further shown in FIG. 9A, a dielectric recapping layer 902 is formed over and/or on the dielectric layer 210 and over and/or on the gate interconnect structure 224. The dielectric recapping layer 902 includes a layer of dielectric material that is used to protect the dielectric layer 210 and the gate interconnect structure 224 during the subsequent process and/or operations to form the source/drain interconnect structure 226. In some implementations, the deposition tool 102 deposits the dielectric recapping layer 902 by a PVD operation, a CVD operation, or another type of deposition operation.

As shown in FIG. 9B, an opening (or a recess) 904 is formed in and through the dielectric recapping layer 902, in and through the dielectric layer 210 and in and though the ESL 208. In particular, the opening 904 is formed from the dielectric recapping layer 902 to a metal source/drain contact 222 (e.g., a conductive layer). As shown in FIG. 9B, the opening 904 includes a bottom surface 906 (which corresponds to the metal source/drain contact 222) and sidewalls 908 (which correspond to the dielectric layer 210 and the ESL 208).

In some implementations, a pattern in a photoresist layer is used to etch the dielectric layer 210, the ESL 208, and the dielectric recapping layer 902 to form the opening 904. In these implementations, the deposition tool 102 forms the photoresist layer on the dielectric layer 210. The exposure tool 104 exposes the photoresist layer to a radiation source to pattern the photoresist layer. The developer tool 106 develops and removes portions of the photoresist layer to expose the pattern. The etch tool 108 etches the dielectric layer 210, the ESL 208, and/or the dielectric recapping layer 902 based on the pattern to form the opening 904. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for etching the opening 904 based on a pattern.

As shown in FIG. 9C, a first portion of the opening 904 is filled with a conductive material (or a conductive material composition) to form the first part 226a of the source/drain interconnect structure 226. In particular, the first part 226a is deposited over the conductive structure (e.g., the metal source/drain contact 222) in the opening 904. In some implementations, the deposition tool 102 performs a PVD operation, a CVD operation, or another type of deposition operation to form the first part 226a of the source/drain interconnect structure 226 in the first portion of the opening 904. In some implementations, the plating tool 112 performs a plating operation such as an electroplating operation to form the first part 226a of the source/drain interconnect structure 226 in the first portion of the opening 904. In some implementations, the deposition tool 102 performs a deposition operation to deposit a seed layer in the opening 904 to promote adhesion of the first part 226a to the sidewalls 908, and the deposition tool 102 performs another deposition operation (or the plating tool 112) performs a plating operation to fill in the remaining portion of the first part 226a over the seed layer. A top surface 910 of the first part 226a of the source/drain interconnect structure 226 is convex (e.g., curved away from a bottom surface of the first part 226a) after performing the deposition operation.

As further shown in FIG. 9C, defects 912 may result in the first part 226a of the source/drain interconnect structure 226 from the formation of the first part 226a. The defects 912 may include, for example, sidewall voids 912a that form from embedded defects 912b aggregating at the sidewalls of the first part 226a. The sidewall voids 912a may continue to aggregate and in some cases may result in discontinuities or other types of defects in the first part 226a.

As shown in FIG. 9D, an annealing operation is subsequently performed on the semiconductor device 200 after the first part 226a of the source/drain interconnect structure 226 is formed. The annealing tool 114 may perform the annealing operation to remove the defects 912 from the first part 226a of the source/drain interconnect structure 226 prior to the opening 904 being fully filled the source/drain interconnect structure 226. In this way, the effectiveness of the annealing operation to remove the defects 912 is increased relative to performing the annealing operation to remove the defects 912 when the opening 904 is fully filled in the source/drain interconnect structure 226. As further shown in FIG. 9D, a top surface 910 of the first part 224a of the gate interconnect structure 224 is convex (or curved away from a bottom of the first part 226a) after performing the annealing operation. The annealing operation may be performed using one or more (or various combinations) of the annealing operation parameters described above in connection with FIGS. 7A-7G.

As shown in FIG. 9E, the remaining portion of the opening 904 is filled with a conductive material (or a conductive material composition) to form the second part 226b of the source/drain interconnect structure 226 in the opening 904. In particular, the second part 226b is deposited over the first part 226a in the opening 702. In some implementations, the conductive material (or the conductive material composition) of the second part 226b is the same conductive material (or the same conductive material composition) as the conductive material (or the conductive material composition) of the first part 226a of the source/drain interconnect structure 226. In some implementations, the conductive material (or the conductive material composition) of the second part 226b is different from the conductive material (or the conductive material composition) of the first part 226a of the source/drain interconnect structure 226.

In some implementations, the deposition tool 102 performs a PVD operation, a CVD operation, or another type of deposition operation to form the second part 226b of the source/drain interconnect structure 226 in the remaining portion of the opening 904. In some implementations, the plating tool 112 performs a plating operation such as an electroplating operation to form the second part 226b of the source/drain interconnect structure 226 in the remaining portion of the opening 904. In some implementations, the deposition tool 102 performs a deposition operation to deposit a seed layer in the opening 904 to promote adhesion of the second part 226b to the sidewalls 908, and the deposition tool 102 performs another deposition operation (or the plating tool 112) performs a plating operation to fill in the remaining portion of the second part 226b over the seed layer.

As further shown in FIG. 9E, the opening 904 may be overfilled to ensure complete filling of the opening 904 with the source/drain interconnect structure 226. In some implementations, another annealing operation is performed for the semiconductor device 200 after forming the second part 226b in the opening 904. In this way, defects in the second part 226b may be removed after forming the second part 226b.As shown in FIG. 9F, a CMP operation is performed to planarize the source/drain interconnect structure 226 and to remove the remaining portions of the dielectric recapping layer 902.

As indicated above, FIGS. 9A-9F are provided as examples. Other examples may differ from what is described with regard to FIG. 9A-9F. For example, while FIGS. 9A-9F show the source/drain interconnect structure 226 being formed subsequent to formation of the gate interconnect structure 224 using the dielectric recapping layer 902, in other implementations, the gate interconnect structure 224 may be formed subsequent to formation of the source/drain interconnect structure 226 using the dielectric recapping layer 902.

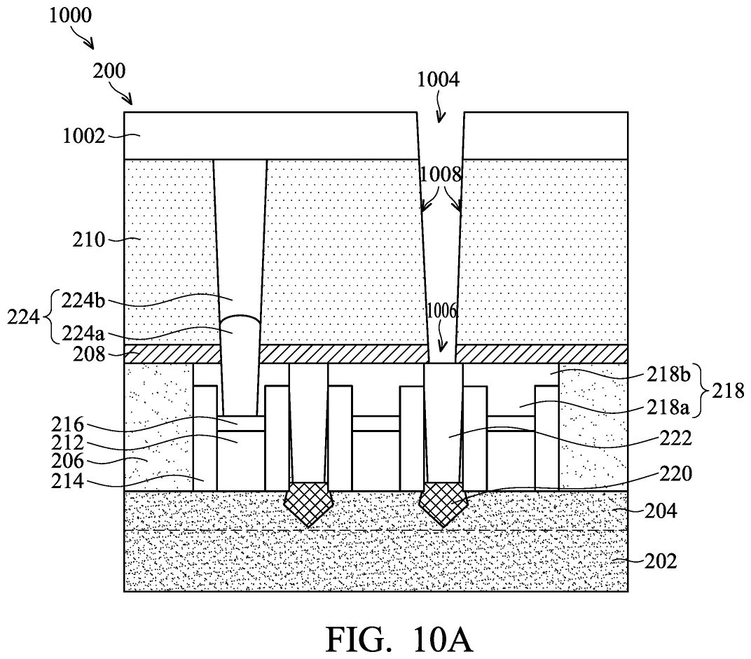

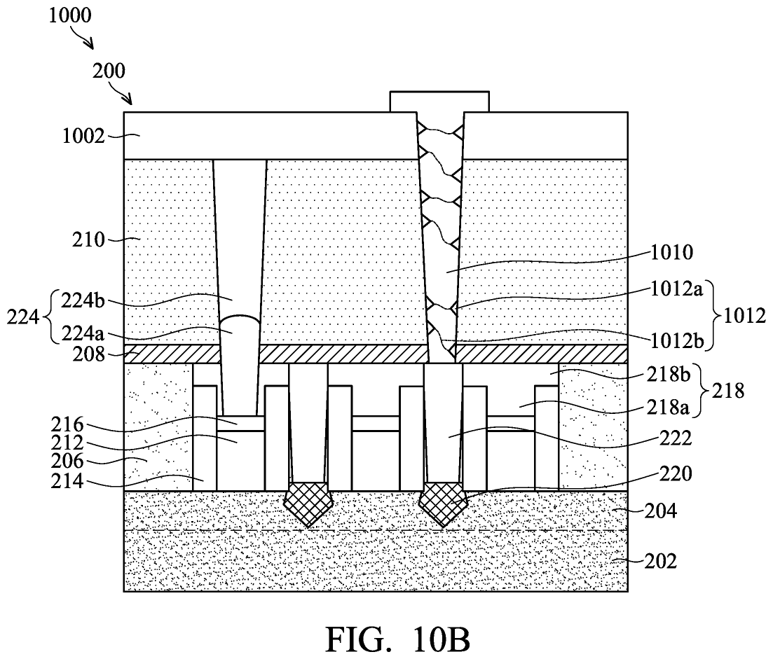

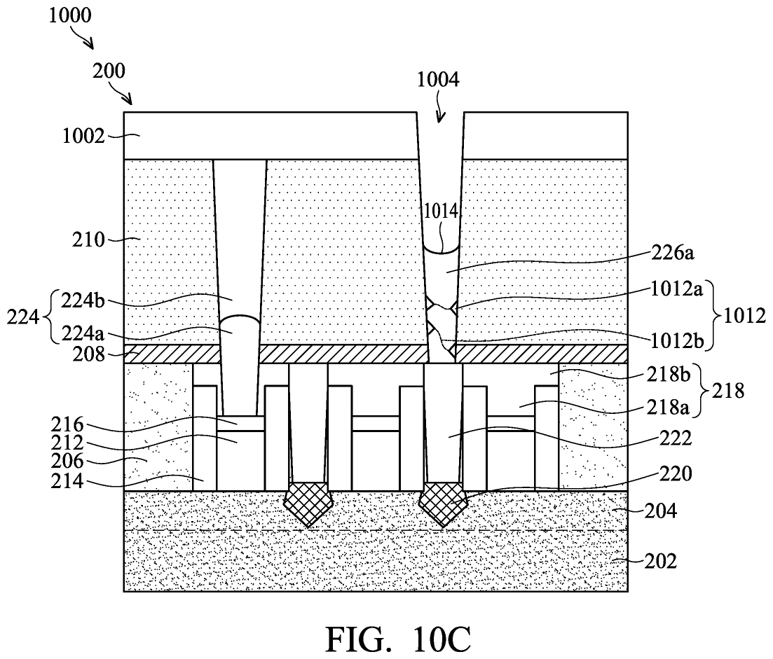

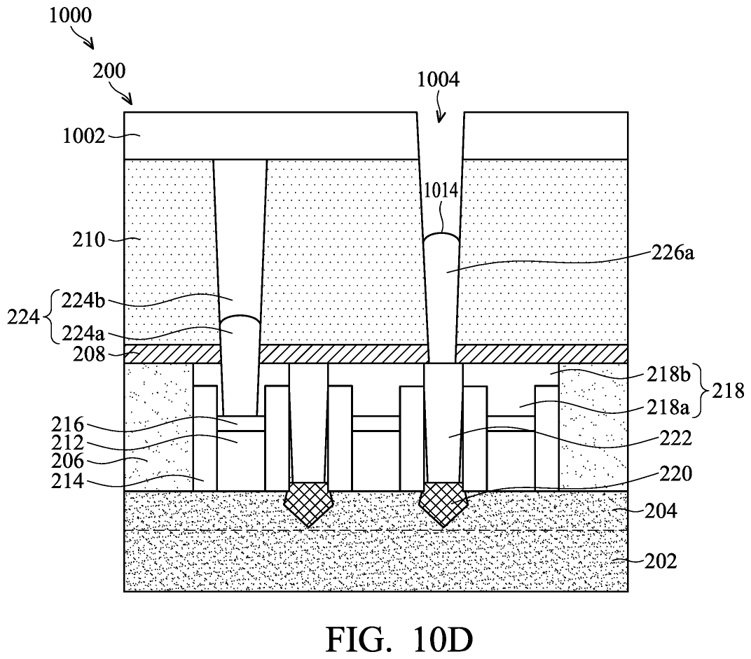

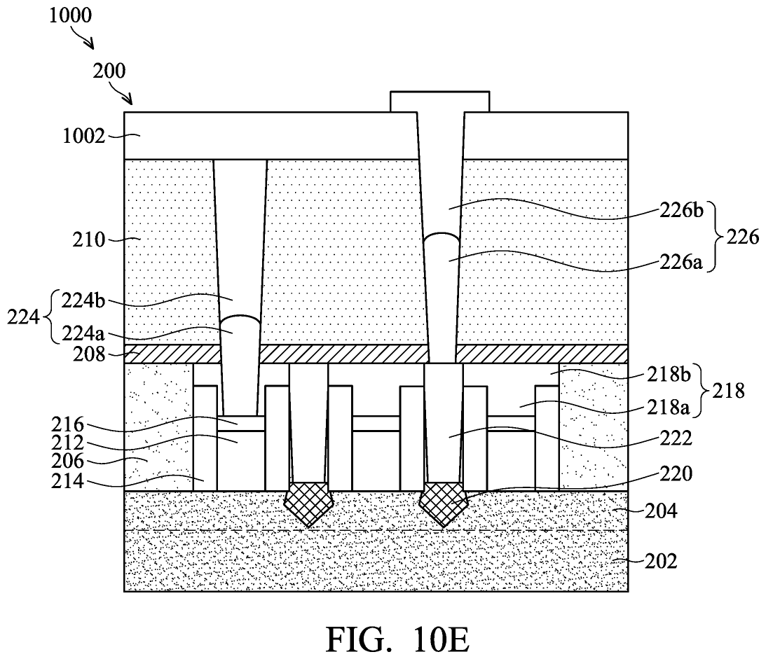

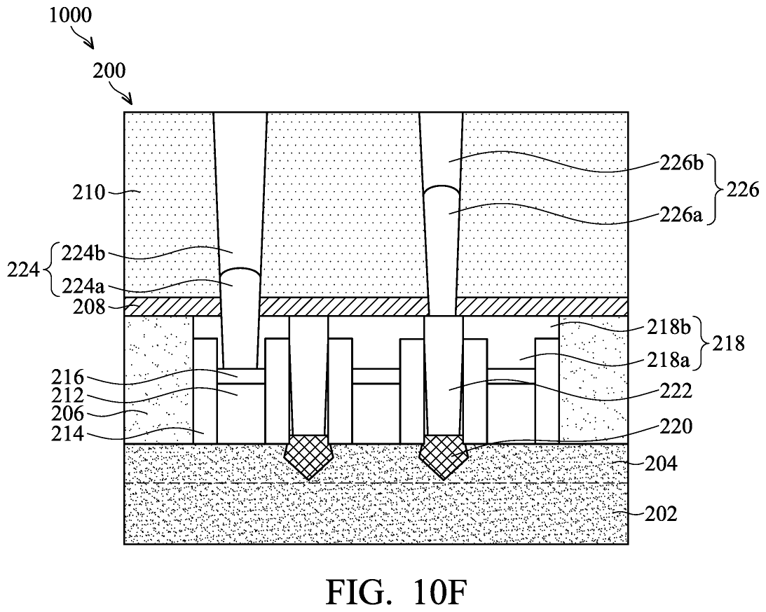

FIGS. 10A-10F are diagrams of an example implementation 1000 described herein. The example implementation 1000 includes another example of forming a two-part interconnect structure such as the source/drain interconnect structure 226 including the first part 226a and the second part 226b included in the semiconductor device 200 illustrated in FIG. 2 and/or elsewhere herein. Turning FIG. 10A, one or more operations may be performed to form the fin structure 204, the metal gate structures 212, the metal capping layers 216, the dielectric capping layers 218, the dielectric layer 206, and/or the metal source/drain contacts 222. Moreover, one or more operations described in connection with FIGS. 7A-7G and/or FIGS. 8A-8F may be performed to form the ESL 208, the dielectric layer 210, and the gate interconnect structure 224 including the first part 224a and the second part 224b.

As further shown in FIG. 10A, a dielectric recapping layer 1002 is formed over and/or on the dielectric layer 210 and over and/or on the gate interconnect structure 224, and an opening (or a recess) 1004 is formed from dielectric recapping layer 1002 to a metal source/drain contact 222 (e.g., a conductive layer). In some implementations, the dielectric recapping layer 1002 and the opening 1004 are formed using the techniques described above in connection with FIGS. 9A-9F. The opening 1004 includes a bottom surface 1006 (which corresponds to the metal source/drain contact 222) and sidewalls 1008 (which correspond to the dielectric layer 210 and the ESL 208).

As shown in FIG. 10B, the opening 1004 (e.g., approximately the entire opening 1004) is filled with a conductive material (or a conductive material composition) to form a sacrificial structure 1010 for the source/drain interconnect structure 226 in the opening 1004. In particular, the sacrificial structure 1010 is deposited over the conductive structure (e.g., the metal source/drain contact 222) in the opening 1004. In some implementations, the deposition tool 102 performs a PVD operation, a CVD operation, or another type of deposition operation to form the sacrificial structure 1010 in the opening 1004. In some implementations, the plating tool 112 performs a plating operation such as an electroplating operation to form the sacrificial structure 1010 in the opening 1004. In some implementations, the deposition tool 102 performs a deposition operation to deposit a seed layer in the opening 1004 to promote adhesion between the sacrificial structure 1010 and the sidewalls 1008 of the opening 1004, and the deposition tool 102 performs another deposition operation (or the plating tool 112) performs a plating operation to fill in the remaining portion of the sacrificial structure 1010 in the opening 1004 over the seed layer.

As further shown in FIG. 10B, defects 1012 may result in the sacrificial structure 1010 from the formation of the sacrificial structure 1010. The defects 1012 may include, for example, sidewall voids 1012a that form from embedded defects 1012b aggregating at the sidewalls of the sacrificial structure 1010. The sidewall voids 1012a may continue to aggregate and in some cases may result in discontinuities or other types of defects in the sacrificial structure 1010.

As shown in FIG. 10C, an etching operation (referred to as an etch back operation) is performed to remove a portion of the sacrificial structure 1010 from the opening 1004. For example, the etch tool 108 may perform the etching operation to remove the portion of the sacrificial structure 1010 from the opening 1004. The remaining portion of the sacrificial structure 1010 in the opening 1004 becomes the first part 226a of the source/drain interconnect structure 226. As further shown in FIG. 10C, a top surface 1014 of the first part 226a of the source/drain interconnect structure 226 is concave (e.g., curved toward the bottom of the first part 226a) after the etching operation.

As shown in FIG. 10D, an annealing operation is performed on the semiconductor device 200 after the etching operation to form the first part 226a of the source/drain interconnect structure 226. The annealing tool 114 may perform the annealing operation to remove the defects 1012 from the first part 226a of the source/drain interconnect structure 226 prior to the opening 1004 being fully filled the source/drain interconnect structure 226. In this way, the effectiveness of the annealing operation to remove the defects 1012 is increased relative to performing the annealing operation to remove the defects 1012 when the opening 1004 is fully filled in the source/drain interconnect structure 226 (or the sacrificial structure 1010). As further shown in FIG. 10D, the top surface 1014 of the first part 226a of the source/drain interconnect structure 226 is convex (e.g., curved away from the bottom of the first part 226a) after performing the annealing operation. The annealing operation may be performed using one or more (or various combinations) of the annealing operation parameters described above in connection with FIGS. 7A-7G.

As shown in FIGS. 10E and 10F respectively, the remaining portion of the opening 1004 is filled with a conductive material (or a conductive material composition) to form the second part 226b of the source/drain interconnect structure 226 in the opening 1004 and a CMP operation is performed to planarize the source/drain interconnect structure 226. In some implementations, another annealing operation is performed for the semiconductor device 200 after forming the second part 226b in the opening 1004. In this way, defects in the second part 226b may be removed after forming the second part 226b.

As indicated above, FIGS. 10A-10F are provided as examples. Other examples may differ from what is described with regard to FIG. 10A-10F. For example, while FIGS. 10A-10F show the source/drain interconnect structure 226 being formed subsequent to formation of the gate interconnect structure 224 using the dielectric recapping layer 1002, in other implementations, the gate interconnect structure 224 may be formed subsequent to formation of the source/drain interconnect structure 226 using the dielectric recapping layer 1002.

FIG. 11 is a diagram of another example implementation 1100 of a portion of the semiconductor device 200 of FIG. 2 described herein. In particular, FIG. 11 illustrates a three-dimensional illustration of a portion of the semiconductor device 200. FIG. 11 illustrates the three-dimensional aspects of the device substrate 202, the fin structure 204, the dielectric layer 206, the ESL 208, the dielectric layer 210, the metal gate structure 212, the sidewall spacers 214, the metal capping layer 216, the source/drain regions 220, the metal source/drain contacts 222, a two-part gate interconnect structure 224 (e.g., including a first part 224a and a second part 224b), and a source/drain interconnect structure 226 (which may include a two-part source/drain interconnect structure 226 including a first part 226a and a second part 226b, or a single-part source/drain interconnect structure 226).

As further shown in FIG. 11, the semiconductor device 200 may include a plurality of STI regions 1102 between the fin structures 204 and below the source/drain regions 220. In other words, the source/drain regions 220 are located on top of the fin structures 204 and above the STI regions 1102. Silicide layers 1104 are further included between the source/drain regions 220 and the associated metal source/drain contacts 222. CESLs 1106 are included between the gate stacks of the semiconductor device 200 and the metal source/drain contacts 222.

As indicated above, FIG. 11 is provided as an example. Other examples may differ from what is described with regard to FIG. 11.

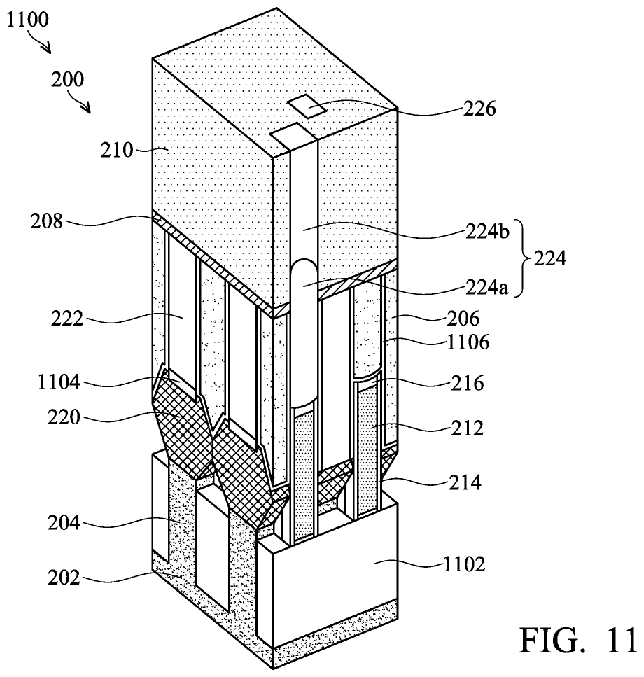

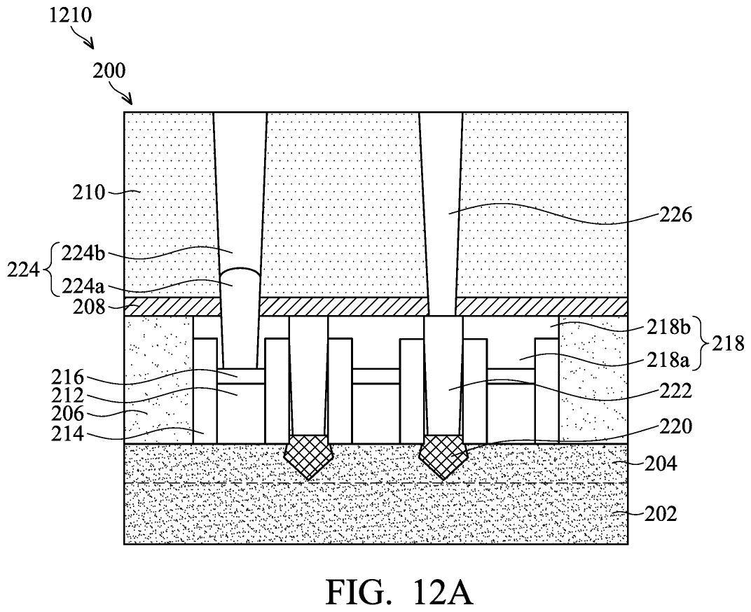

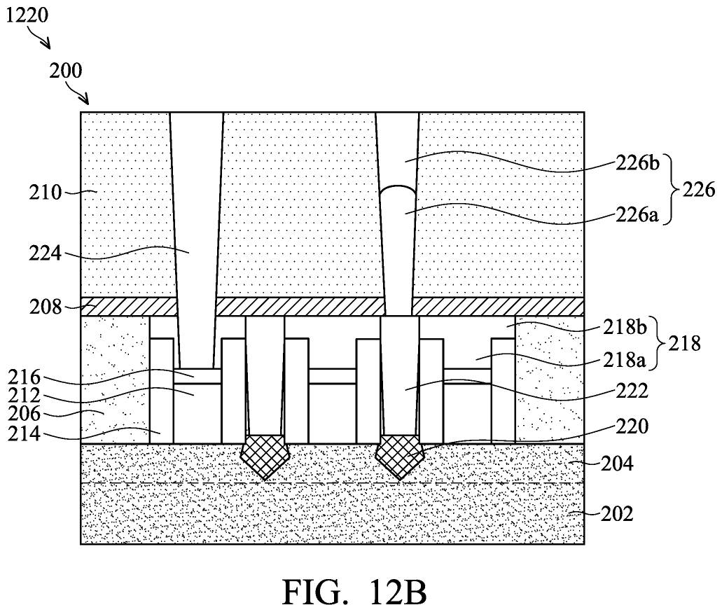

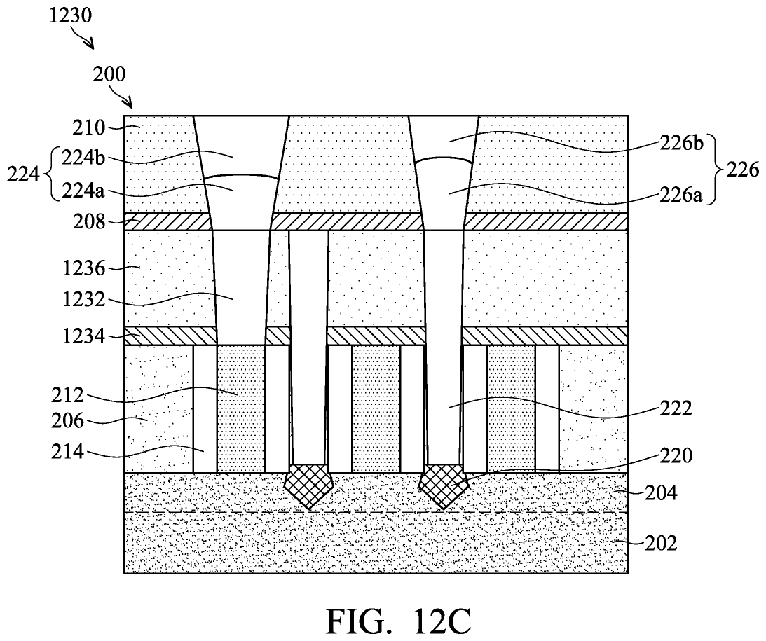

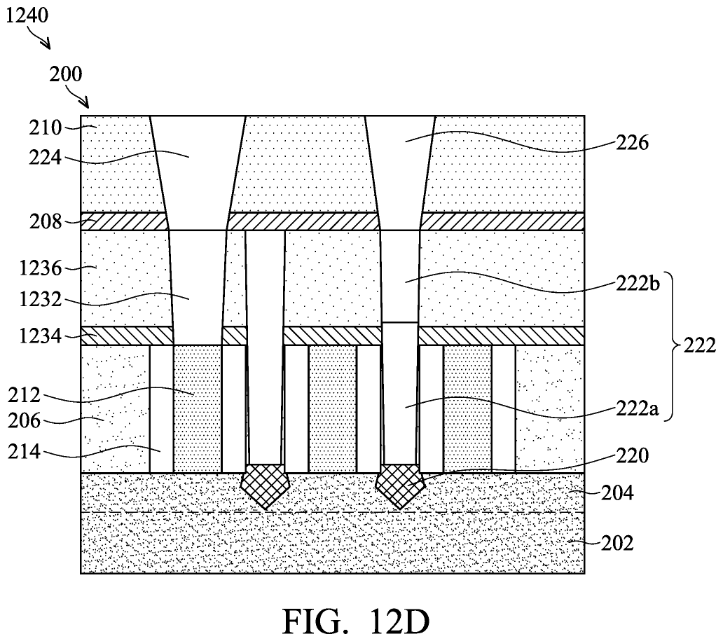

FIGS. 12A-12D are diagrams of other example implementations of a portion of the semiconductor device 200 of FIG. 2 described herein. FIGS. 12A-12C illustrate various combinations of gate interconnect structure types and source/drain interconnect structure types, including two-part gate interconnect structures, single-part gate interconnect structures, two-part source/drain interconnect structures, and/or single-part source/drain interconnect structures.

As shown in FIG. 12A, an example implementation 1210 of a portion of the semiconductor device 200 includes similar structures as illustrated in FIG. 2. However, the portion of the semiconductor device 200 illustrated in the example implementation 1210 of FIG. 12A includes a single-part source/drain interconnect structure 226 (e.g., a source/drain interconnect structure that is formed or filled by a single deposition operation and a single annealing operation) in combination with a two-part gate interconnect structure 224 that includes the first part 224a and the second part 224b. The combination of the two-part gate interconnect structure 224 and the single-part source/drain interconnect structure 226 enables the process for forming the single-part source/drain interconnect structure 226 to be simplified while enabling increased defect removal and increased interconnect performance for the two-part gate interconnect structure 224.

As shown in FIG. 12B, an example implementation 1220 of a portion of the semiconductor device 200 includes similar structures as illustrated in FIG. 2. However, the portion of the semiconductor device 200 illustrated in the example implementation 1220 of FIG. 12B includes a single-part gate interconnect structure 224 (e.g., a gate interconnect structure that is formed or filled by a single deposition operation and a single annealing operation) in combination with a two-part source/drain interconnect structure 226 that includes the first part 226a and the second part 226b.The combination of the single-part gate interconnect structure 224 and the two-part source/drain interconnect structure 226 enables the process for forming the single-part gate interconnect structure 224 to be simplified while enabling increased defect removal and increased interconnect performance for the two-part source/drain interconnect structure 226.

As shown in FIG. 12C, an example implementation 1230 of a portion of the semiconductor device 200 includes similar structures as illustrated in FIG. 2. However, in the example implementation 1230, the semiconductor device 200 further includes a metal gate contact 1232. The metal capping layer 216 and/or the dielectric capping layer 218 may be omitted from the semiconductor device 200 in the example implementation 1230, and the sidewall spacers 214 may approximately extend from fin structure 204 to another ESL 1234. Similarly, the metal gate structure 212 may approximately extend from fin structure 204 to another ESL 1234. Another dielectric layer 1236 (e.g., an ILD1 layer) may be included between the dielectric layer 206 (e.g., the ILDO layer) and the dielectric layer 210 (e.g., the ILD2 layer). The metal source/drain contacts 222 may extend from the source/drain regions 220 to approximately the top surface of the dielectric layer 1236, similar to the metal gate contact 1232 (which may be referred to as an MP). In this way, the height of the top surface of the metal gate contact 1232 and the height of the top surface of the metal source/drain contacts 222 are approximately the same height. Accordingly, the vertical position of the top surface of the metal gate contact 1232 in the semiconductor device 200 and the vertical position of the top surface of the metal source/drain contacts 222 are approximately equal.

As further shown in FIG. 12C, the gate interconnect structure 224 is electrically and/or physically connected to the metal gate contact 1232. The source/drain interconnect structure 226 is electrically and/or physically connected to a metal source/drain contact 222. The gate interconnect structure 224 and the source/drain interconnect structure 226 may be located in and/or through the ESL 208 and in and/or through the dielectric layer 210. In this way, the height of the gate interconnect structure 224 and the height of the source/drain interconnect structure 226 are approximately the same height.

As further shown in FIG. 12C, the gate interconnect structure 224 and/or the source/drain interconnect structure 226 include a two-part interconnect structure. For example, the gate interconnect structure 224 may include the first part 224a that is electrically and/or physically connected to the metal gate contact 1232, and the second part 224b over and/or on the first part 224a. The first part 224a may extend through the ESL 208 and a portion of the dielectric layer 210, and the second part 224b may extend through another portion of the dielectric layer 210. The first part 224a and the second part 224b illustrated in FIG. 12C may be formed by similar operations and/or techniques described herein, for example, in connection with FIGS. 7A-7G and/or 8A-8F remove defects and/or minimize defect formation in the gate interconnect structure 224.

As another example, the source/drain interconnect structure 226 may include the first part 226a that is electrically and/or physically connected to a metal source/drain contact 222, and the second part 226b over and/or on the first part 226a. The first part 226a may extend through the ESL 208 and a portion of the dielectric layer 210, and the second part 226b may extend through another portion of the dielectric layer 210. The first part 226a and the second part 226b illustrated in FIG. 12C may be formed by similar operations and/or techniques described herein, for example, in connection with FIGS. 9A-9F and/or 10A-10F remove defects and/or minimize defect formation in the source/drain interconnect structure 226.

In the example implementation 1230 illustrated in FIG. 12C, the bottom width of the first part 224a of the gate interconnect structure 224 may be included in a range of approximately 8 millimeters to approximately 18 millimeters. In the example implementation 1230 illustrated in FIG. 12C, the bottom width of the first part 226a of the source/drain interconnect structure 226 may be included in a range of approximately 8 millimeters to approximately 18 millimeters. In the example implementation 1230 illustrated in FIG. 12C, the bottom width of the second part 224b of the gate interconnect structure 224 may be included in a range of approximately 10 millimeters to approximately 20 millimeters. In the example implementation 1230 illustrated in FIG. 12C, the bottom width of the second part 226b of the source/drain interconnect structure 226 may be included in a range of approximately 10 millimeters to approximately 20 millimeters.

In the example implementation 1230 illustrated in FIG. 12C, the height or thickness of the first part 224a of the gate interconnect structure 224 may be included in a range of approximately 5 millimeters to approximately 20 millimeters. In the example implementation 1230 illustrated in FIG. 12C, the height or thickness of the second part 224b of the gate interconnect structure 224 may be included in a range of approximately 5 millimeters to approximately 40 millimeters. In the example implementation 1230 illustrated in FIG. 12C, the height or thickness of the first part 226a of the source/drain interconnect structure 226 may be included in a range of approximately 5 millimeters to approximately 20 millimeters. In the example implementation 1230 illustrated in FIG. 12C, the height or thickness of the second part 226b of the source/drain interconnect structure 226 may be included in a range of approximately 5 millimeters to approximately 40 millimeters.

As shown in FIG. 12D, an example implementation 1240 of a portion of the semiconductor device 200 includes similar structures as illustrated in FIG. 12D. However, in the example implementation 1240, the semiconductor device 200 further includes a metal source/drain contact 222 includes a two-part contact structure. The two-part contact structure includes a first part 222a that is electrically and/or physically connected to source/drain region 220, and the second part 222b over and/or on the first part 222a. The first part 222a and the second part 222b illustrated in FIG. 12C may be formed by similar operations and/or techniques described herein, for example, in connection with FIGS. 7A-7G and/or 8A-8F remove defects and/or minimize defect formation in the metal source/drain contact 222.

The first part 222a may extend through at least a portion of the dielectric layer 206, through at least a portion of the ESL 208, and/or through at least a portion of the dielectric layer 1236, and the second part 222b may extend through at least a portion of the dielectric layer 206, through at least a portion of the ESL 208, and/or through at least a portion of the dielectric layer 1236. An interface between the first part 222a and the second part 222b may be included between a top surface and a bottom surfaces of the dielectric layer 206, between a top surface and a bottom surface of the ESL 208, or between a top surface and a bottom surface of the dielectric layer 1236.

In some implementations, a two-part metal gate contact 1232 may be included in a similar manner as the two-part metal source/drain contact.

As indicated above, FIGS. 12A-12D are provided as examples. Other examples may differ from what is described with regard to FIG. 12A-12D. Moreover one or more implementations described in connection with FIGS. 12A-12D may be combined with one or more other implementations described in connection with FIGS. 12A-12D and/or described elsewhere herein.

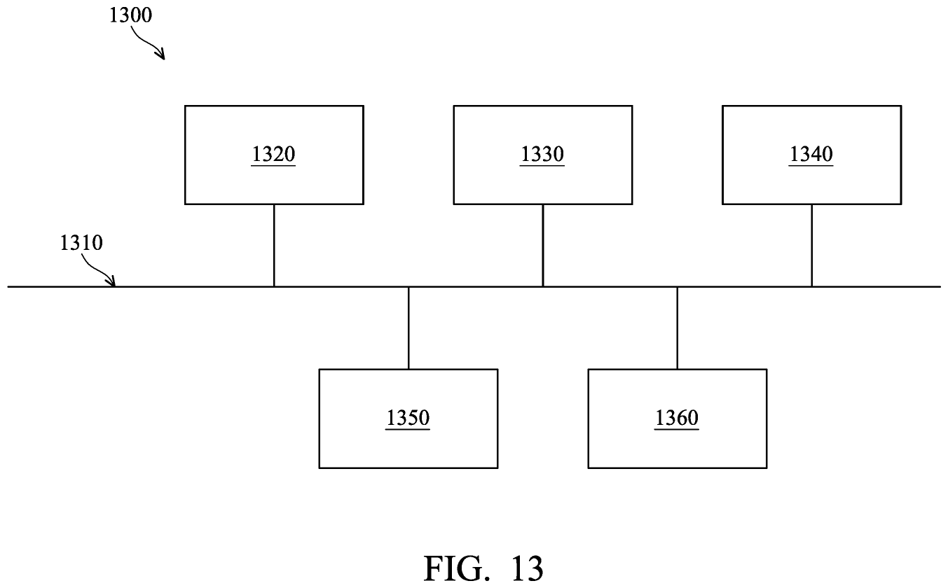

FIG. 13 is a diagram of example components of a device 1300. In some implementations, one or more of the semiconductor processing tools 102-114 and/or the wafer/die transport tool 116 may include one or more devices 1300 and/or one or more components of device 1300. As shown in FIG. 13, device 1300 may include a bus 1310, a processor 1320, a memory 1330, an input component 1340, an output component 1350, and a communication component 1360.

Bus 1310 includes one or more components that enable wired and/or wireless communication among the components of device 1300. Bus 1310 may couple together two or more components of FIG. 13, such as via operative coupling, communicative coupling, electronic coupling, and/or electric coupling. Processor 1320 includes a central processing unit, a graphics processing unit, a microprocessor, a controller, a microcontroller, a digital signal processor, a field-programmable gate array, an application-specific integrated circuit, and/or another type of processing component. Processor 1320 is implemented in hardware, firmware, or a combination of hardware and software. In some implementations, processor 1320 includes one or more processors capable of being programmed to perform one or more operations or processes described elsewhere herein.

Memory 1330 includes volatile and/or nonvolatile memory. For example, memory 1330 may include random access memory (RAM), read only memory (ROM), a hard disk drive, and/or another type of memory (e.g., a flash memory, a magnetic memory, and/or an optical memory). Memory 1330 may include internal memory (e.g., RAM, ROM, or a hard disk drive) and/or removable memory (e.g., removable via a universal serial bus connection). Memory 1330 may be a non-transitory computer-readable medium. Memory 1330 stores information, instructions, and/or software (e.g., one or more software applications) related to the operation of device 1300. In some implementations, memory 1330 includes one or more memories that are coupled to one or more processors (e.g., processor 1320), such as via bus 1310.

Input component 1340 enables device 1300 to receive input, such as user input and/or sensed input. For example, input component 1340 may include a touch screen, a keyboard, a keypad, a mouse, a button, a microphone, a switch, a sensor, a global positioning system sensor, an accelerometer, a gyroscope, and/or an actuator. Output component 1350 enables device 1300 to provide output, such as via a display, a speaker, and/or a light-emitting diode. Communication component 1360 enables device 1300 to communicate with other devices via a wired connection and/or a wireless connection. For example, communication component 1360 may include a receiver, a transmitter, a transceiver, a modem, a network interface card, and/or an antenna.

Device 1300 may perform one or more operations or processes described herein. For example, a non-transitory computer-readable medium (e.g., memory 1330) may store a set of instructions (e.g., one or more instructions or code) for execution by processor 1320. Processor 1320 may execute the set of instructions to perform one or more operations or processes described herein. In some implementations, execution of the set of instructions, by one or more processors 1320, causes the one or more processors 1320 and/or the device 1300 to perform one or more operations or processes described herein. In some implementations, hardwired circuitry may be used instead of or in combination with the instructions to perform one or more operations or processes described herein. Additionally, or alternatively, processor 1320 may be configured to perform one or more operations or processes described herein. Thus, implementations described herein are not limited to any specific combination of hardware circuitry and software.

The number and arrangement of components shown in FIG. 13 are provided as an example. Device 1300 may include additional components, fewer components, different components, or differently arranged components than those shown in FIG. 13. Additionally, or alternatively, a set of components (e.g., one or more components) of device 1300 may perform one or more functions described as being performed by another set of components of device 1300.

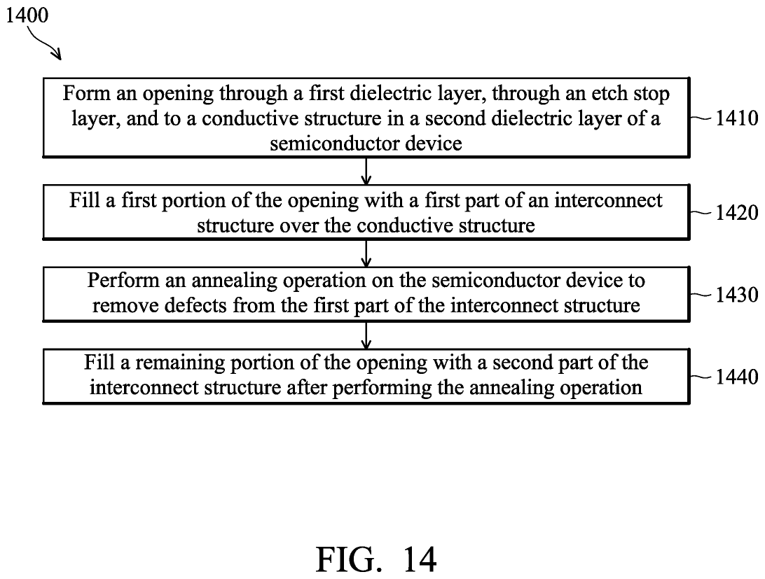

FIG. 14 is a flowchart of an example process 1400 related to forming a semiconductor interconnect structure described herein. In some implementations, one or more process blocks of FIG. 14 may be performed by one or more semiconductor processing tools (e.g., one or more of the semiconductor processing tools 102-114). Additionally, or alternatively, one or more process blocks of FIG. 14 may be performed by one or more components of device 1300, such as processor 1320, memory 1330, input component 1340, output component 1350, and/or communication component 1360.

As shown in FIG. 14, process 1400 may include forming an opening through a first dielectric layer, through an etch stop layer, and to a conductive structure in a second dielectric layer of a semiconductor device (block 1410). For example, the one or more semiconductor processing tools 102-114 may form an opening (e.g., the opening 702, 904) through a first dielectric layer (e.g., the dielectric layer 210), through an etch stop layer (e.g., the ESL 208), and to a conductive structure (e.g., the metal capping layer 216, the metal source/drain contact 222) in a second dielectric layer (e.g., the dielectric layer 206) of the semiconductor device 200, as described herein.

As further shown in FIG. 14, process 1400 may include filling a first portion of the opening with a first part of an interconnect structure over the conductive structure (block 1420). For example, the one or more semiconductor processing tools 102-114 may fill a first portion of the opening with a first part (e.g., the first part 224a, the first part 226a) of an interconnect structure (e.g., the gate interconnect structure 224, the source/drain interconnect structure 226) over the conductive structure, as described herein.

As further shown in FIG. 14, process 1400 may include performing an annealing operation on the semiconductor device to remove defects from the first part of the interconnect structure (block 1430). For example, the one or more semiconductor processing tools 102-114 may perform an annealing operation on the semiconductor device 200 to remove defects (e.g., defects 710, defects 912) from the first part of the interconnect structure, as described above. In some implementations, a top surface (e.g., the top surface 708, the top surfaces 910) of the first part of the interconnect structure is convex after performing the annealing operation.

As further shown in FIG. 14, process 1400 may include filling a remaining portion of the opening with a second part of the interconnect structure after performing the annealing operation (block 1440). For example, the one or more semiconductor processing tools 102-114 may fill a remaining portion of the opening with a second part (e.g., the second part 224b, the second part 226b) of the interconnect structure after performing the annealing operation, as described above.

Process 1400 may include additional implementations, such as any single implementation or any combination of implementations described below and/or in connection with one or more other processes described elsewhere herein.

In a first implementation, process 1400 includes performing another annealing operation on the semiconductor device 200 to remove defects from the second part of the interconnect structure, and performing a CMP operation on the second part of the interconnect structure. In a second implementation, alone or in combination with the first implementation, performing the annealing operation includes performing the annealing operation using a combination of gases including nitrogen (N₂), helium (He), and argon (Ar), a temperature range of approximately 200 degrees Celsius to approximately 450 degrees Celsius, and a vacuum pressure range of approximately 0.5 Tor to approximately 10 Tor. In a third implementation, alone or in combination with one or more of the first and second implementations, performing the annealing operation includes performing the annealing operation using hydrogen gas (H2), a temperature range of approximately 160 degrees Celsius to approximately 450 degrees Celsius, and a vacuum pressure range of approximately 0.5 Tor to approximately 10 Tor.

In a fourth implementation, alone or in combination with one or more of the first through third implementations, process 1400 includes forming a dielectric recapping layer (e.g., the dielectric recapping layer 902, the dielectric recapping layer 1002) on the first dielectric layer and on the second part of the interconnect structure after filling the remaining portion of the opening with the second part of the interconnect structure, forming another opening (e.g., the opening 904, the opening 1004) through the dielectric recapping layer, through the first dielectric layer, through the etch stop layer, and to another conductive structure (e.g., the metal source/drain contact 222) in the second dielectric layer of the semiconductor device, forming a first part (e.g., the first part 226a) of another interconnect structure (e.g., the source/drain interconnect structure 226) in the other opening, performing another annealing operation on the first part of the other interconnect structure to remove defects (e.g., the defects 912, the defects 1012) from the first part of the other interconnect structure, and filling a remaining portion of the other opening with a second part (e.g., the second part 226b) of the other interconnect structure after performing the other annealing operation. In a fifth implementation, alone or in combination with one or more of the first through fourth implementations, a vertical position of a bottom surface of the first part of the interconnect structure is lower in the semiconductor device 200 relative to a bottom surface of the first part of the other interconnect structure.

Although FIG. 14 shows example blocks of process 1400, in some implementations, process 1400 may include additional blocks, fewer blocks, different blocks, or differently arranged blocks than those depicted in FIG. 14. Additionally, or alternatively, two or more of the blocks of process 1400 may be performed in parallel.

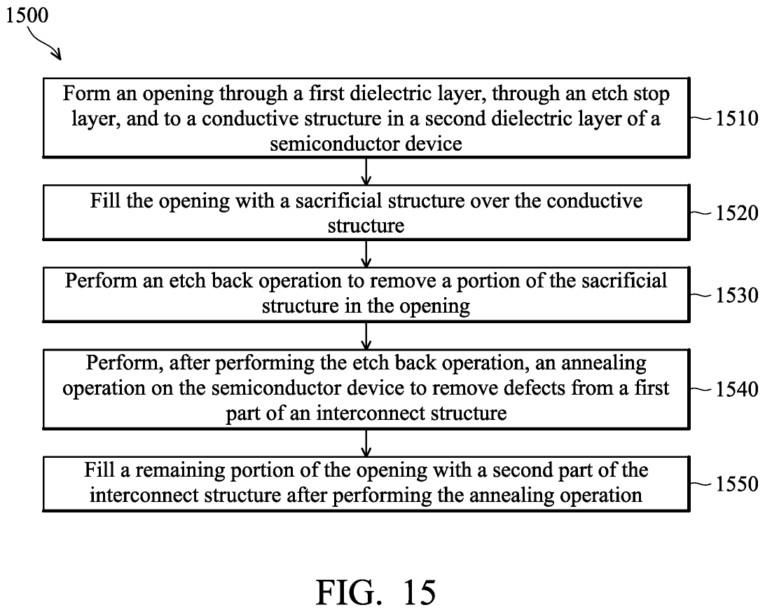

FIG. 15 is a flowchart of an example process 1500 related to forming a semiconductor interconnect structure described herein. In some implementations, one or more process blocks of FIG. 15 may be performed by one or more semiconductor processing tools (e.g., one or more of the semiconductor processing tools 102-114). Additionally, or alternatively, one or more process blocks of FIG. 15 may be performed by one or more components of device 1300, such as processor 1320, memory 1330, input component 1340, output component 1350, and/or communication component 1360.

As shown in FIG. 15, process 1500 may include forming an opening through a first dielectric layer, through an etch stop layer, and to a conductive structure in a second dielectric layer of a semiconductor device (block 1510). For example, the one or more semiconductor processing tools 102-114 may form an opening (e.g., the opening 802, the opening 1004) through a first dielectric layer (e.g., the dielectric layer 210), through an etch stop layer (e.g., the ESL 208), and to a conductive structure (e.g., the metal capping layer 216, metal source/drain contact 222) in a second dielectric layer (e.g., the dielectric layer 206) of the semiconductor device 200, as described above.

As further shown in FIG. 15, process 1500 may include filling the opening with a sacrificial structure over the conductive structure (block 1520). For example, the one or more semiconductor processing tools 102-114 may fill the opening with a sacrificial structure (e.g., the sacrificial structure 808, the sacrificial structure 1010) over the conductive structure, as described above.

As further shown in FIG. 15, process 1500 may include performing an etch back operation to remove a portion of the sacrificial structure in the opening (block 1530). For example, the one or more semiconductor processing tools 102-114 may perform an etch back operation to remove a portion of the sacrificial structure in the opening, as described above. In some implementations, a remaining portion of the sacrificial structure in the opening includes a first part (e.g., the first part 224a, the first part 226a) of an interconnect structure (e.g., the gate interconnect structure 224, the source/drain interconnect structure 226) over the conductive structure.

As further shown in FIG. 15, process 1500 may include performing, after performing the etch back operation, an annealing operation on the semiconductor device to remove defects from the first part of the interconnect structure (block 1540). For example, the one or more semiconductor processing tools 102-114 may perform, after performing the etch back operation, an annealing operation on the semiconductor device to remove defects (e.g., the defects 810, the defects 1012) from the first part of the interconnect structure, as described above. In some implementations, a top surface (e.g., the top surface 812, the top surfaces 1014) of the first part of the interconnect structure is convex after performing the annealing operation.

As further shown in FIG. 15, process 1500 may include filling a remaining portion of the opening with a second part of the interconnect structure after performing the annealing operation (block 1550). For example, the one or more semiconductor processing tools 102-114 may fill a remaining portion of the opening with a second part (e.g., the second part 224b, the second part 226b) of the interconnect structure after performing the annealing operation, as described above.

Process 1500 may include additional implementations, such as any single implementation or any combination of implementations described below and/or in connection with one or more other processes described elsewhere herein.

In a first implementation, the top surface of the first part of the interconnect structure is concave after performing the etch back operation and prior to performing the annealing operation. In a second implementation, alone or in combination with the first implementation, process 1500 includes performing another annealing operation on the semiconductor device 200 to remove defects from the second part of the interconnect structure, and performing a CMP operation on the second part of the interconnect structure after performing the other annealing operation.

In a third implementation, alone or in combination with one or more of the first and second implementations, the conductive structure includes a metal source/drain contact 222, and a vertical position of the first part of the interconnect structure is greater than a vertical position of the metal source/drain contact 222. In a fourth implementation, alone or in combination with one or more of the first through third implementations, process 1500 includes forming a dielectric recapping layer (e.g., the dielectric recapping layer 902, the dielectric recapping layer 1002) on the first dielectric layer and on the second part of the interconnect structure after filling the remaining portion of the opening with the second part of the interconnect structure, forming another opening (e.g., the opening 904, the opening 1004) through the dielectric recapping layer, through the first dielectric layer, through the etch stop layer, and to another conductive structure (e.g., the metal source/drain contact 222) in the second dielectric layer of the semiconductor device, forming a first part (e.g., the first part 226a) of another interconnect structure (e.g., the source/drain interconnect structure 226) in the other opening, performing another annealing operation on the first part of the other interconnect structure to remove defects (e.g., defects 912, defects 1012) from the first part of the other interconnect structure, and filling a remaining portion of the other opening with a second part (e.g., the second part 226b) of the other interconnect structure after performing the other annealing operation.

Although FIG. 15 shows example blocks of process 1500, in some implementations, process 1500 may include additional blocks, fewer blocks, different blocks, or differently arranged blocks than those depicted in FIG. 15. Additionally, or alternatively, two or more of the blocks of process 1500 may be performed in parallel.

In this way, the two-step anneal techniques described herein include performing a first anneal operation on a first portion of the interconnect, filling the remaining portion of the interconnect, and then performing a second anneal operation on the interconnect. The two-step anneal techniques described herein enable the removal of defects in an interconnect structure, particularly for high aspect ratio interconnect structures. Accordingly, the two-step anneal techniques described herein may be used to fabricate defect free or near defect free interconnect structures in a semiconductor device. This reduces contact resistance for the interconnect structures, reduces premature device failure for the semiconductor device, increases manufacturing yield, and increases tolerance of the interconnect structures to subsequent processing operations, among other examples.

As described in greater detail above, some implementations described herein provide a semiconductor device. The semiconductor device includes a metal gate structure. The semiconductor device includes a gate interconnect structure, connected to the metal gate structure, including a first part orientated toward the metal gate structure and a second part on the first part. An interface between the first part and the second part is curved, and the gate interconnect structure is tapered between a top of the second part and a bottom of the first part in an approximately continuous and uniform manner.

As described in greater detail above, some implementations described herein provide a method. The method includes forming an opening through a first dielectric layer, through an etch stop layer, and to a conductive structure in a second dielectric layer of a semiconductor device. The method includes filling a first portion of the opening with a first part of an interconnect structure over the conductive structure. The method includes performing an annealing operation on the semiconductor device to remove defects from the first part of the interconnect structure, where a top surface of the first part of the interconnect structure is convex after performing the annealing operation. The method includes filling a remaining portion of the opening with a second part of the interconnect structure after performing the annealing operation.

As described in greater detail above, some implementations described herein provide a method. The method includes forming an opening through a first dielectric layer, through an etch stop layer, and to a conductive structure in a second dielectric layer of a semiconductor device. The method includes filling the opening with a sacrificial structure over the conductive structure. The method includes performing an etch back operation to remove a portion of the sacrificial structure in the opening, where a remaining portion of the sacrificial structure in the opening includes a first part of an interconnect structure over the conductive structure. The method includes performing, after performing the etch back operation, an annealing operation on the semiconductor device to remove defects from the first part of the interconnect structure, where a top surface of the first part of the interconnect structure is convex after performing the annealing operation. The method includes filling a remaining portion of the opening with a second part of the interconnect structure after performing the annealing operation.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an opening through a first dielectric layer, through an etch stop layer, and to a conductive structure in a second dielectric layer of a semiconductor device;
filling a first portion of the opening with a first part of an interconnect structure over the conductive structure;
performing an annealing operation on the semiconductor device to remove defects from the first part of the interconnect structure,
wherein a top surface of the first part of the interconnect structure is convex after performing the annealing operation; and
filling a remaining portion of the opening with a second part of the interconnect structure after performing the annealing operation.

2. The method of claim 1, further comprising:
performing another annealing operation on the semiconductor device to remove defects from the second part of the interconnect structure; and
performing a chemical mechanical planarization (CMP) operation on the second part of the interconnect structure.

3. The method of claim 1, wherein performing the annealing operation comprises:
performing the annealing operation using:
a combination of gases including nitrogen (N₂), helium (He), and argon (Ar),
a temperature range of approximately 200 degrees Celsius to approximately 450 degrees Celsius, and
a vacuum pressure range of approximately 0.5 Tor to approximately 10 Tor.

4. The method of claim 1, wherein performing the annealing operation comprises:
performing the annealing operation using:
hydrogen gas (H₂),
a temperature range of approximately 160 degrees Celsius to approximately 450 degrees Celsius, and
a vacuum pressure range of approximately 0.5 Tor to approximately 10 Tor.

5. The method of claim 1, further comprising:
forming a dielectric recapping layer on the first dielectric layer and on the second part of the interconnect structure after filling the remaining portion of the opening with the second part of the interconnect structure;
forming another opening through the dielectric recapping layer, through the first dielectric layer, through the etch stop layer, and to another conductive structure in the second dielectric layer of the semiconductor device;
forming a first part of another interconnect structure in the other opening;
performing another annealing operation on the first part of the other interconnect structure to remove defects from the first part of the other interconnect structure; and
filling a remaining portion of the other opening with a second part of the other interconnect structure after performing the other annealing operation.

6. The method of claim 5, wherein a vertical position of a bottom surface of the first part of the interconnect structure is lower in the semiconductor device relative to a bottom surface of the first part of the other interconnect structure.

7. A method, comprising:
forming an opening through a first dielectric layer, through an etch stop layer, and to a conductive structure in a second dielectric layer of a semiconductor device;
filling the opening with a sacrificial structure over the conductive structure;
performing an etch back operation to remove a portion of the sacrificial structure in the opening,
wherein a remaining portion of the sacrificial structure in the opening comprises a first part of an interconnect structure over the conductive structure;
performing, after performing the etch back operation, an annealing operation on the semiconductor device to remove defects from the first part of the interconnect structure,
wherein a top surface of the first part of the interconnect structure is convex after performing the annealing operation; and
filling a remaining portion of the opening with a second part of the interconnect structure after performing the annealing operation.

8. The method of claim 7, further comprising:
wherein the top surface of the first part of the interconnect structure is concave after performing the etch back operation and prior to performing the annealing operation.

9. The method of claim 7, further comprising:
performing another annealing operation on the semiconductor device to remove defects from the second part of the interconnect structure; and
performing a chemical mechanical planarization (CMP) operation on the second part of the interconnect structure after performing the other annealing operation.

10. The method of claim 7, wherein the conductive structure comprises a metal source/drain contact; and
wherein a vertical position of the first part of the interconnect structure is greater than a vertical position of the metal source/drain contact.

11. The method of claim 7, further comprising:
forming a dielectric recapping layer on the first dielectric layer and on the second part of the interconnect structure after filling the remaining portion of the opening with the second part of the interconnect structure;
forming another opening through the dielectric recapping layer, through the first dielectric layer, through the etch stop layer, and to another conductive structure in the second dielectric layer of the semiconductor device;
forming a first part of another interconnect structure in the other opening;
performing another annealing operation on the first part of the other interconnect structure to remove defects from the first part of the other interconnect structure; and
filling a remaining portion of the other opening with a second part of the other interconnect structure after performing the other annealing operation.

12. A semiconductor device, comprising:
a metal gate structure; and
a gate interconnect structure, connected to the metal gate structure, comprising:
a first part orientated toward the metal gate structure, and
a second part on the first part,
wherein an interface between the first part and the second part is curved, and
wherein the gate interconnect structure is tapered between a top of the second part and a bottom of the first part in an approximately continuous and uniform manner, and the first part and the second part comprise different metal materials.

13. The semiconductor device of claim 12, further comprising:
a metal source/drain contact; and
a source/drain interconnect structure, comprising:
a third part orientated toward the metal source/drain contact; and
a fourth part on the third part,
wherein an interface between the third part and the fourth part is curved, and
wherein the source/drain interconnect structure is tapered between a top of the fourth part and a bottom of the third part in an approximately continuous and uniform manner.

14. The semiconductor device of claim 13, wherein the interface between the first part and the second part, and the interface between the third part and the fourth part, are at different vertical positions in the semiconductor device.

15. The semiconductor device of claim 13, wherein the interface between the first part and the second part is located at a lower height relative to a height of the interface between the third part and the fourth part.

16. The semiconductor device of claim 13, wherein a ratio of a volume of the second part to a volume of the first part is in a range of approximately 1:1 to approximately 1:3; and
wherein a ratio of a volume of the third part to a volume of the fourth part is in a range of approximately 1:2 to approximately 1:4.

17. The semiconductor device of claim 13, wherein the gate interconnect structure is connected to the metal gate structure by a gate contact; and
wherein a height of a top surface of the gate contact and a height of a top surface of the metal source/drain contact are approximately a same height.

18. The semiconductor device of claim 12, wherein a distance between a center of a curve of the interface and a base of the curve of the interface is in a range of greater than 0 nanometers to approximately 3 nanometers.

19. The semiconductor device of claim 12, wherein the interface between the first part and the second part is located at a same level as:
a capping layer over a gate included in the semiconductor device,
an etch stop layer above the metal gate structure, or
an interlayer dielectric (ILD) layer above the etch stop layer.

20. The semiconductor device of claim 12, wherein the gate interconnect structure is directly connected to the metal gate structure, or
wherein the gate interconnect structure is connected to the metal gate structure by an intervening conductive layer,
wherein a top surface of the intervening conductive layer is lower than a top surface of a gate spacer associated with the metal gate structure.
